(19) United States
(12) Patent Application Publication
(10) Pub. No.: US 2014/0021798 A1
(43) Pub. Date: Jan. 23, 2014

(54) WIRELESS ENERGY TRANSFER WITH REPEATER RESONATORS

(71) Applicant: WiTricity Corporation, Watertown, MA (US)

(72) Inventors: Morris P. Kesler, Bedford, MA (US); Katherine L. Hall, Arlington, MA (US); Konrad J. Kulikowski, Denver, CO (US); Alexander P. McCauley, Cambridge, MA (US); Andre B. Kurs, Chestnut Hill, MA (US); Simon Verghese, Arlington, MA (US)

(73) Assignee: WiTricity Corporation, Watertown, MA (US)

(21) Appl. No.: 13/944,693

(22) Filed: Jul. 17, 2013

Related U.S. Application Data
(60) Provisional application No. 61/672,423, filed on Jul. 17, 2012.

(51) Int. Cl. H02J 17/00; G01R 19/165

(52) U.S. Cl. CPC H02J 17/00; G01R 19/16533
USPC 307/104; 324/76.11

(57) ABSTRACT

Described herein are systems for wireless energy transfer distribution over a defined area. Energy may be distributed over the area via a plurality of repeater, source, and device resonators. The resonators within the area may be tunable and the distribution of energy or magnetic fields within the area may be configured depending on device position and power needs.

### CROSS-REFERENCE TO RELATED APPLICATIONS

This application claims the benefit of U.S. Provisional Appl. No. 61/672,433 filed Jul. 17, 2012 which is incorporated herein by reference.

The following applications are incorporated herein by reference: U.S. application Ser. No. 13/369,104 filed Feb. 8, 2012; U.S. application Ser. No. 13/737,708 filed Jan. 9, 2013 and U.S. application Ser. No. 13/232,868 filed Sep. 14, 2011.

### BACKGROUND

1. Field

This disclosure relates to wireless energy transfer, methods, systems and apparati to accomplish such transfer, and applications.

2. Description of the Related Art

Energy distribution over an area to moving devices or devices that may be often repositioned is unpractical with wired connections. Moving and changing devices create the possibility of wire tangles, tripping hazards, and the like. Wireless energy transfer over a larger area may be difficult when the area or region in which devices may be present may be large compared to the size of the device.

Therefore a need exists for methods and designs for energy distribution that is wire free but easy to deploy and configurable while may deliver sufficient power to be practical to power many household and industrial devices.

### SUMMARY

Resonators and resonator assemblies may be positioned to distribute wireless energy over a larger area. The wireless energy transfer resonators and components that may be used have been described in, for example, in commonly owned U.S. patent application Ser. No. 12/789,611 published on Sep. 23, 2010 as U.S. Pat. Pub. No. 2010/0237709 and entitled “RESONATOR ARRAYS FOR WIRELESS ENERGY TRANSFER,” and U.S. patent application Ser. No. 12/722,050 published on Jul. 22, 2010 as U.S. Pat. Pub. No. 2010/0181843 and entitled “WIRELESS ENERGY TRANSFER FOR REFRIGERATOR APPLICATION” the contents of which are incorporated in their entirety as if fully set forth herein.

In accordance with an exemplary and non-limiting embodiment, a system for wireless energy distribution over a volume, the system comprises a source device coupled to an energy source, the source device comprising at least one source resonator that is configured to generate an oscillating magnetic field with a frequency and wherein the source device has a source energized volume and at least one repeater device, the repeater device comprising at least one repeater resonator and positioned in a defined area and in coupling proximity to the source device, wherein the repeater device provides an effective wireless energy system energized volume that is larger than the source energized volume, and wherein the source device is operable to detect the presence of a repeater device.

In accordance with another exemplary and non-limiting embodiment, a method of detecting the location of a repeater device using a source device comprises energizing a source resonator of the source device, measuring a voltage and a current on the source resonator, comparing the voltage and current measurements with expected measurements, determining if a repeater resonator of the repeater device is within a coupling distance to the source resonator and indicating a presence of a repeater resonator within the coupling distance.

### BRIEF DESCRIPTION OF FIGURES

FIG. 1 is a system block diagram of wireless energy transfer configurations.

FIGS. 2A-2F are exemplary structures and schematics of resonator structures.

FIGS. 3A-3B are diagram showing two resonator configurations with repeater resonators.

FIGS. 4A-4B are diagram showing two resonator configurations with repeater resonators.

FIG. 5A is a diagram showing a configuration with two repeater resonators and 5B is a diagram showing a resonator configuration with a device resonator acting as a repeater resonator.

FIG. 6 is a diagram of a system utilizing a repeater resonator with a desk environment.

FIG. 7 is a diagram of a system utilizing a resonator that may be operated in multiple modes.

FIG. 8 is a circuit block diagram of the power and control circuitry of a resonator configured to have multiple modes of operation.

FIG. 9A and FIG. 9B are diagrams of embodiments of a wireless power enabled floor tile.

FIG. 10 is a block diagram of an embodiment of a wireless power enabled floor tile.

FIG. 11 is diagram of a wireless power enables floor system.

FIG. 12 is diagram of a cuttable sheet of resonators.

FIG. 13A is an isometric view of a wireless drink coaster, FIG. 13B is an isometric view of a wireless drink coaster with a mug.

FIG. 14 is an isometric view of an electronic device with a wireless dongle.

FIG. 15 is an isometric view of a wireless source with a drink coaster and a dongle.

FIG. 16 is an isometric view of a wireless source with a drink coaster and a dongle.

FIG. 17 is an isometric view of an embodiment of a resonator structure.

FIG. 18 is an isometric view of an embodiment of a resonator structure.

FIG. 19 is an isometric view of an embodiment of a wireless energy transfer system for charging phones.

FIG. 20 is an isometric view of a wireless source comprising overlapping repeater resonator coils.

FIG. 21 is a wireless source comprising overlapping repeater resonator coils.

FIG. 22 is a diagram of a wireless energy transfer system with a repeater under the table.

FIG. 23 is a diagram of a wireless energy transfer system implemented with one type of resonator coil.

FIG. 24 is a block diagram of an embodiment of a wireless energy transfer system.

FIG. 25 is a flow diagram of an embodiment of a method for mapping the location of a repeater device using a source device.

### DETAILED DESCRIPTION

As described above, this disclosure relates to wireless energy transfer using coupled electromagnetic resonators. However, such energy transfer is not restricted to electromagnetic resonators, and the wireless energy transfer systems described herein are more general and may be implemented using a wide variety of resonators and resonant objects.

As those skilled in the art will recognize, important considerations for resonator-based power transfer include resonator efficiency and resonator coupling. Extensive discussion of such issues, e.g., coupled mode theory (CMT), coupling coefficients and factors, quality factors (also referred to as Q-factors), and impedance matching is provided, for example, in U.S. patent application Ser. No. 12/789,611 published on Sep. 23, 2010 as US 20100237709 and entitled “RESONATOR ARRAYS FOR WIRELESS ENERGY TRANSFER,” and U.S. patent application Ser. No. 12/722,050 published on Jul. 22, 2010 as US 20100181843 and entitled “WIRELESS ENERGY TRANSFER FOR REFRIGERATOR APPLICATION” and incorporated herein by reference in its entirety as if fully set forth herein.

A resonator may be defined as a resonant structure that can store energy in at least two different forms, and where the stored energy oscillates between the two forms. The resonant structure will have a specific oscillation mode with a resonant (modal) frequency, f, and a resonant (modal) field. The angular resonant frequency, ω, may be defined as ω=2πf, the resonant period, T, may be defined as T=1/f=2λ/ω, and the resonant wavelength, λ, may be defined as λ=c/f, where c is the speed of the associated field waves (light, for electromagnetic resonators). In the absence of loss mechanisms, coupling mechanisms or external energy supplying or draining mechanisms, the total amount of energy stored by the resonator, W, would stay fixed, but the form of the energy would oscillate between the two forms supported by the resonator, wherein one form would be maximum when the other is minimum and vice versa.

For example, a resonator may be constructed such that the two forms of stored energy are magnetic energy and electric energy. Further, the resonator may be constructed such that the electric energy stored by the electric field is primarily confined within the structure while the magnetic energy stored by the magnetic field is primarily in the region surrounding the resonator. In other words, the total electric and magnetic energies would be equal, but their localization would be different. Using such structures, energy exchange between at least two structures may be mediated by the resonant magnetic near-field of the at least two resonators. These types of resonators may be referred to as magnetic resonators.

An important parameter of resonators used in wireless power transmission systems is the Quality Factor, or Q-factor, or Q, of the resonator, which characterizes the energy decay and is inversely proportional to energy losses of the resonator. It may be defined as Q=ω*W/P, where P is the time-averaged power lost at steady state. That is, a resonator with a high-Q has relatively low intrinsic losses and can store energy for a relatively long time. Since the resonator loses energy at its intrinsic decay rate, 2Γ, its Q, also referred to as its intrinsic Q, is given by Q=ω/2Γ. The quality factor also represents the number of oscillation periods, T, it takes for the energy in the resonator to decay by a factor of e^{-2π}. Note that the quality factor or intrinsic quality factor or Q of the resonator is that due only to intrinsic loss mechanisms. The Q of a resonator connected to, or coupled to a power generator, g, or load, l, may be called the “loaded quality factor” or the “loaded Q”. The Q of a resonator in the presence of an extraneous object that is not intended to be part of the energy transfer system may be called the “perturbed quality factor” or the “perturbed Q”.

Resonators, coupled through any portion of their near-fields may interact and exchange energy. The efficiency of this energy transfer can be significantly enhanced if the resonators operate at substantially the same resonant frequency. By way of example, but not limitation, imagine a source resonator with Qₛ and a device resonator with Q_{d}. High-Q wireless energy transfer systems may utilize resonators that are high-Q. The Q of each resonator may be high. The geometric mean of the resonator Q's, \sqrt{QₛQ_{d}} may also or instead be high.

The coupling factor, k, is a number between 0≦|k|≦1, and it may be independent (or nearly independent) of the resonant frequencies of the source and device resonators, when those are placed at sub-wavelength distances. Rather the coupling factor k may be determined mostly by the relative geometry and the distance between the source and device resonators where the physical decay-law of the field mediating their coupling is taken into account. The coupling coefficient used in CMT, κ=k\sqrt{ωₛω_{d}}/2, may be a strong function of the resonant frequencies, as well as other properties of the resonator structures. In applications for wireless energy transfer utilizing the near-fields of the resonators, it is desirable to have the size of the resonator be much smaller than the resonant wavelength, so that power lost by radiation is reduced. In some embodiments, high-Q resonators are sub-wavelength structures. In some electromagnetic embodiments, high-Q resonator structures are designed to have resonant frequencies higher than 100 kHz. In other embodiments, the resonant frequencies may be less than 1 GHz.

In exemplary embodiments, the power radiated into the far-field by these sub wavelength resonators may be further reduced by lowering the resonant frequency of the resonators and the operating frequency of the system. In other embodiments, the far field radiation may be reduced by arranging for the far fields of two or more resonators to interfere destructively in the far field.

In a wireless energy transfer system a resonator may be used as a wireless energy source, a wireless energy capture device, a repeater or a combination thereof. In embodiments a resonator may alternate between transferring energy, receiving energy or relaying energy. In a wireless energy transfer system one or more magnetic resonators may be coupled to an energy source and be energized to produce an oscillating magnetic near-field. Other resonators that are within the oscillating magnetic near-fields may capture these fields and convert the energy into electrical energy that may be used to power or charge a load thereby enabling wireless transfer of useful energy.

The so-called “useful” energy in a useful energy exchange is the energy or power that must be delivered to a device in order to power or charge it at an acceptable rate. The transfer efficiency that corresponds to a useful energy exchange may be system or application-dependent. For example, high power vehicle charging applications that transfer kilowatts of power may need to be at least 80% efficient in order to supply useful amounts of power resulting in a useful energy exchange sufficient to recharge a vehicle battery without significantly heating up various components of the transfer system. In some consumer electronics applications, a useful energy exchange may include any energy transfer efficiencies greater than 10%, or any other amount acceptable to keep rechargeable batteries “topped off” and running for long periods of time. In implanted medical device applications, a useful energy exchange may be any exchange that does not harm the patient but that extends the life of a battery or wakes up a sensor or monitor or stimulator. In such applications, 100 mW of power or less may be useful. In distributed sensing applications, power transfer of microwatts may be useful, and transfer efficiencies may be well below 1%.

A useful energy exchange for wireless energy transfer in a powering or recharging application may be efficient, highly efficient, or efficient enough, as long as the wasted energy levels, heat dissipation, and associated field strengths are within tolerable limits and are balanced appropriately with related factors such as cost, weight, size, and the like.

The resonators may be referred to as source resonators, device resonators, first resonators, second resonators, repeater resonators, and the like. Implementations may include three (3) or more resonators. For example, a single source resonator may transfer energy to multiple device resonators or multiple devices. Energy may be transferred from a first device to a second, and then from the second device to the third, and so forth. Multiple sources may transfer energy to a single device or to multiple devices connected to a single device resonator or to multiple devices connected to multiple device resonators. Resonators may serve alternately or simultaneously as sources, devices, and/or they may be used to relay power from a source in one location to a device in another location. Intermediate electromagnetic resonators may be used to extend the distance range of wireless energy transfer systems and/or to generate areas of concentrated magnetic near-fields. Multiple resonators may be daisy-chained together, exchanging energy over extended distances and with a wide range of sources and devices. For example, a source resonator may transfer power to a device resonator via several repeater resonators. Energy from a source may be transferred to a first repeater resonator, the first repeater resonator may transfer the power to a second repeater resonator and the second to a third and so on until the final repeater resonator transfers its energy to a device resonator. In this respect the range or distance of wireless energy transfer may be extended and/or tailored by adding repeater resonators. High power levels may be split between multiple sources, transferred to multiple devices and recombined at a distant location.

The resonators may be designed using coupled mode theory models, circuit models, electromagnetic field models, and the like. The resonators may be designed to have tunable characteristic sizes. The resonators may be designed to handle different power levels. In exemplary embodiments, high power resonators may require larger conductors and higher current or voltage rated components than lower power resonators.

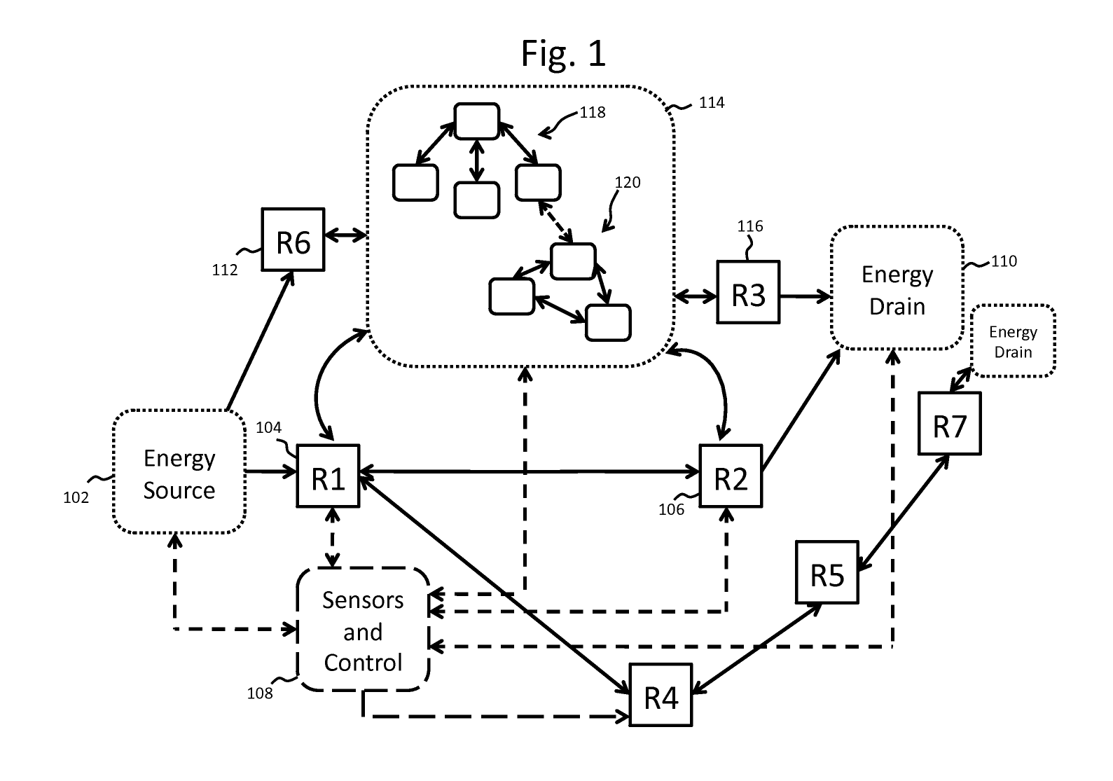

FIG. 1 shows a diagram of exemplary configurations and arrangements of a wireless energy transfer system. A wireless energy transfer system may include at least one source resonator (R1) 104 (optionally R6, 112) coupled to an energy source 102 and optionally a sensor and control unit 108. The energy source may be a source of any type of energy capable of being converted into electrical energy that may be used to drive the source resonator 104. The energy source may be a battery, a solar panel, the electrical mains, a wind or water turbine, an electromagnetic resonator, a generator, and the like. The electrical energy used to drive the magnetic resonator is converted into oscillating magnetic fields by the resonator. The oscillating magnetic fields may be captured by other resonators which may be device resonators (R2) 106, (R3) 116 that are optionally coupled to an energy drain 110. The oscillating fields may be optionally coupled to repeater resonators (R4, R5) that are configured to extend or tailor the wireless energy transfer region. Device resonators may capture the magnetic fields in the vicinity of source resonator(s), repeater resonators and other device resonators and convert them into electrical energy that may be used by an energy drain. The energy drain 110 may be an electrical, electronic, mechanical or chemical device and the like configured to receive electrical energy. Repeater resonators may capture magnetic fields in the vicinity of source, device and repeater resonator(s) and may pass the energy on to other resonators.

A wireless energy transfer system may comprise a single source resonator 104 coupled to an energy source 102 and a single device resonator 106 coupled to an energy drain 110. In embodiments a wireless energy transfer system may comprise multiple source resonators coupled to one or more energy sources and may comprise multiple device resonators coupled to one or more energy drains.

In embodiments the energy may be transferred directly between a source resonator 104 and a device resonator 106. In other embodiments the energy may be transferred from one or more source resonators 104, 112 to one or more device resonators 106, 116 via any number of intermediate resonators which may be device resonators, source resonators, repeater resonators, and the like. Energy may be transferred via a network or arrangement of resonators 114 that may include subnetworks 118, 120 arranged in any combination of topologies such as token ring, mesh, ad hoc, and the like.

In embodiments the wireless energy transfer system may comprise a centralized sensing and control system 108. In embodiments parameters of the resonators, energy sources, energy drains, network topologies, operating parameters, etc. may be monitored and adjusted from a control processor to meet specific operating parameters of the system. A central control processor may adjust parameters of individual components of the system to optimize global energy transfer efficiency, to optimize the amount of power transferred, and the like. Other embodiments may be designed to have a substantially distributed sensing and control system. Sensing and control may be incorporated into each resonator or group of resonators, energy sources, energy drains, and the like and may be configured to adjust the parameters of the individual components in the group to maximize or minimize the power delivered, to maximize energy transfer efficiency in that group and the like.

In embodiments, components of the wireless energy transfer system may have wireless or wired data communication links to other components such as devices, sources, repeaters, power sources, resonators, and the like and may transmit or receive data that can be used to enable the distributed or centralized sensing and control. A wireless communication channel may be separate from the wireless energy transfer channel, or it may be the same. In one embodiment the resonators used for power exchange may also be used to exchange information. In some cases, information may be exchanged by modulating a component in a source or device circuit and sensing that change with port parameter or other monitoring equipment. Resonators may signal each other by tuning, changing, varying, dithering, and the like, the resonator parameters such as the impedance of the resonators which may affect the reflected impedance of other resonators in the system. The systems and methods described herein may enable the simultaneous transmission of power and communication signals between resonators in wireless power transmission systems, or it may enable the transmission of power and communication signals during different time periods or at different frequencies using the same magnetic fields that are used during the wireless energy transfer. In other embodiments wireless communication may be enabled with a separate wireless communication channel such as WiFi, Bluetooth, Infrared, NFC, and the like.

In embodiments, a wireless energy transfer system may include multiple resonators and overall system performance may be improved by control of various elements in the system. For example, devices with lower power requirements may tune their resonant frequency away from the resonant frequency of a high-power source that supplies power to devices with higher power requirements. For another example, devices needing less power may adjust their rectifier circuits so that they draw less power from the source. In these ways, low and high power devices may safely operate or charge from a single high power source. In addition, multiple devices in a charging zone may find the power available to them regulated according to any of a variety of consumption control algorithms such as First-Come-First-Serve, Best Effort, Guaranteed Power, etc. The power consumption algorithms may be hierarchical in nature, giving priority to certain users or types of devices, or it may support any number of users by equally sharing the power that is available in the source. Power may be shared by any of the multiplexing techniques described in this disclosure.

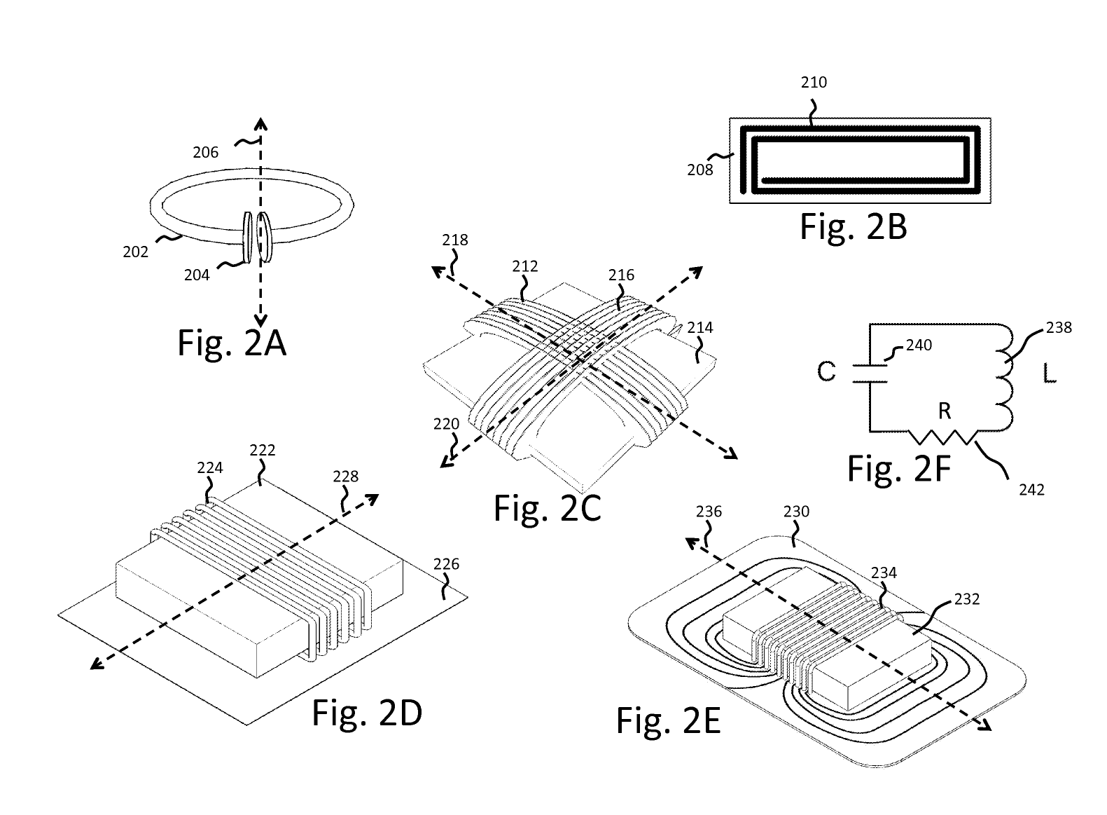

In embodiments electromagnetic resonators may be realized or implemented using a combination of shapes, structures, and configurations. Electromagnetic resonators may include an inductive element, a distributed inductance, or a combination of inductances with a total inductance, L, and a capacitive element, a distributed capacitance, or a combination of capacitances, with a total capacitance, C. A minimal circuit model of an electromagnetic resonator comprising capacitance, inductance and resistance, is shown in FIG. 2F. The resonator may include an inductive element 238 and a capacitive element 240. Provided with initial energy, such as electric field energy stored in the capacitor 240, the system will oscillate as the capacitor discharges transferring energy into magnetic field energy stored in the inductor 238 which in turn transfers energy back into electric field energy stored in the capacitor 240. Intrinsic losses in these electromagnetic resonators include losses due to resistance in the inductive and capacitive elements and to radiation losses, and are represented by the resistor, R, 242 in FIG. 2F.

FIG. 2A shows a simplified drawing of an exemplary magnetic resonator structure. The magnetic resonator may include a loop of conductor acting as an inductive element 202 and a capacitive element 204 at the ends of the conductor loop. The inductor 202 and capacitor 204 of an electromagnetic resonator may be bulk circuit elements, or the inductance and capacitance may be distributed and may result from the way the conductors are formed, shaped, or positioned, in the structure.

For example, the inductor 202 may be realized by shaping a conductor to enclose a surface area, as shown in FIG. 2A. This type of resonator may be referred to as a capacitively-loaded loop inductor. Note that we may use the terms “loop” or “coil” to indicate generally a conducting structure (wire, tube, strip, etc.), enclosing a surface of any shape and dimension, with any number of turns. In FIG. 2A, the enclosed surface area is circular, but the surface may be any of a wide variety of other shapes and sizes and may be designed to achieve certain system performance specifications. In embodiments the inductance may be realized using inductor elements, distributed inductance, networks, arrays, series and parallel combinations of inductors and inductances, and the like. The inductance may be fixed or variable and may be used to vary impedance matching as well as resonant frequency operating conditions.

There are a variety of ways to realize the capacitance required to achieve the desired resonant frequency for a resonator structure. Capacitor plates 204 may be formed and utilized as shown in FIG. 2A, or the capacitance may be distributed and be realized between adjacent windings of a multi-loop conductor. The capacitance may be realized using capacitor elements, distributed capacitance, networks, arrays, series and parallel combinations of capacitances, and the like. The capacitance may be fixed or variable and may be used to vary impedance matching as well as resonant frequency operating conditions.

The inductive elements used in magnetic resonators may contain more than one loop and may spiral inward or outward or up or down or in some combination of directions. In general, the magnetic resonators may have a variety of shapes, sizes and number of turns and they may be composed of a variety of conducing materials. The conductor 210, for example, may be a wire, a Litz wire, a ribbon, a pipe, a trace formed from conducting ink, paint, gels, and the like or from single or multiple traces printed on a circuit board. An exemplary embodiment of a trace pattern on a substrate 208 forming inductive loops is depicted in FIG. 2B.

In embodiments the inductive elements may be formed using magnetic materials of any size, shape thickness, and the like, and of materials with a wide range of permeability and loss values. These magnetic materials may be solid blocks, they may enclose hollow volumes, they may be formed from many smaller pieces of magnetic material tiled and or stacked together, and they may be integrated with conducting sheets or enclosures made from highly conducting materials. Conductors may be wrapped around the magnetic materials to generate the magnetic field. These conductors may be wrapped around one or more than one axis of the structure. Multiple conductors may be wrapped around the magnetic materials and combined in parallel, or in series, or via a switch to form customized near-field patterns and/or to orient the dipole moment of the structure. Examples of resonators comprising magnetic material are depicted in FIGS. 2C, 2D, 2E. In FIG. 2D the resonator comprises loops of conductor 224 wrapped around a core of magnetic material 222 creating a structure that has a magnetic dipole moment 228 that is parallel to the axis of the loops of the conductor 224. The resonator may comprise multiple loops of conductor 216, 212 wrapped in orthogonal directions around the magnetic material 214 forming a resonator with a magnetic dipole moment 218, 220 that may be oriented in more than one direction as depicted in FIG. 2C, depending on how the conductors are driven.

An electromagnetic resonator may have a characteristic, natural, or resonant frequency determined by its physical properties. This resonant frequency is the frequency at which the energy stored by the resonator oscillates between that stored by the electric field, W_{E}, (W_{E}=q²/2C, where q is the charge on the capacitor, C) and that stored by the magnetic field, W_{B}, (W_{B}=Li²/2, where i is the current through the inductor, L) of the resonator. The frequency at which this energy is exchanged may be called the characteristic frequency, the natural frequency, or the resonant frequency of the resonator, and is given by ω,

$$ω = 2 π f = \sqrt{\frac{1}{LC}} .$$

The resonant frequency of the resonator may be changed by tuning the inductance, L, and/or the capacitance, C, of the resonator. In one embodiment system parameters are dynamically adjustable or tunable to achieve as close as possible to optimal operating conditions. However, based on the discussion above, efficient enough energy exchange may be realized even if some system parameters are not variable or components are not capable of dynamic adjustment.

In embodiments a resonator may comprise an inductive element coupled to more than one capacitor arranged in a network of capacitors and circuit elements. In embodiments the coupled network of capacitors and circuit elements may be used to define more than one resonant frequency of the resonator. In embodiments a resonator may be resonant, or partially resonant, at more than one frequency.

In embodiments, a wireless power source may comprise of at least one resonator coil coupled to a power supply, which may be a switching amplifier, such as a class-D amplifier or a class-E amplifier or a combination thereof. In this case, the resonator coil is effectively a power load to the power supply. In embodiments, a wireless power device may comprise of at least one resonator coil coupled to a power load, which may be a switching rectifier, such as a class-D rectifier or a class-E rectifier or a combination thereof. In this case, the resonator coil is effectively a power supply for the power load, and the impedance of the load directly relates also to the work-drainage rate of the load from the resonator coil. The efficiency of power transmission between a power supply and a power load may be impacted by how closely matched the output impedance of the power source is to the input impedance of the load. Power may be delivered to the load at a maximum possible efficiency, when the input impedance of the load is equal to the complex conjugate of the internal impedance of the power supply. Designing the power supply or power load impedance to obtain a maximum power transmission efficiency is often called “impedance matching”, and may also referred to as optimizing the ratio of useful-to-lost powers in the system. Impedance matching may be performed by adding networks or sets of elements such as capacitors, inductors, transformers, switches, resistors, and the like, to form impedance matching networks between a power supply and a power load. In embodiments, mechanical adjustments and changes in element positioning may be used to achieve impedance matching. For varying loads, the impedance matching network may include variable components that are dynamically adjusted to ensure that the impedance at the power supply terminals looking towards the load and the characteristic impedance of the power supply remain substantially complex conjugates of each other, even in dynamic environments and operating scenarios.

In embodiments, impedance matching may be accomplished by tuning the duty cycle, and/or the phase, and/or the frequency of the driving signal of the power supply or by tuning a physical component within the power supply, such as a capacitor. Such a tuning mechanism may be advantageous because it may allow impedance matching between a power supply and a load without the use of a tunable impedance matching network, or with a simplified tunable impedance matching network, such as one that has fewer tunable components for example. In embodiments, tuning the duty cycle, and/or frequency, and/or phase of the driving signal to a power supply may yield a dynamic impedance matching system with an extended tuning range or precision, with higher power, voltage and/or current capabilities, with faster electronic control, with fewer external components, and the like.

In some wireless energy transfer systems the parameters of the resonator such as the inductance may be affected by environmental conditions such as surrounding objects, temperature, orientation, number and position of other resonators and the like. Changes in operating parameters of the resonators may change certain system parameters, such as the efficiency of transferred power in the wireless energy transfer. For example, high-conductivity materials located near a resonator may shift the resonant frequency of a resonator and detune it from other resonant objects. In some embodiments, a resonator feedback mechanism is employed that corrects its frequency by changing a reactive element (e.g., an inductive element or capacitive element). In order to achieve acceptable matching conditions, at least some of the system parameters may need to be dynamically adjustable or tunable. All the system parameters may be dynamically adjustable or tunable to achieve approximately the optimal operating conditions. However, efficient enough energy exchange may be realized even if all or some system parameters are not variable. In some examples, at least some of the devices may not be dynamically adjusted. In some examples, at least some of the sources may not be dynamically adjusted. In some examples, at least some of the intermediate resonators may not be dynamically adjusted. In some examples, none of the system parameters may be dynamically adjusted.

In some embodiments changes in parameters of components may be mitigated by selecting components with characteristics that change in a complimentary or opposite way or direction when subjected to differences in operating environment or operating point. In embodiments, a system may be designed with components, such as capacitors, that have an opposite dependence or parameter fluctuation due to temperature, power levels, frequency, and the like. In some embodiments, the component values as a function of temperature may be stored in a look-up table in a system microcontroller and the reading from a temperature sensor may be used in the system control feedback loop to adjust other parameters to compensate for the temperature induced component value changes.

In some embodiments the changes in parameter values of components may be compensated with active tuning circuits comprising tunable components. Circuits that monitor the operating environment and operating point of components and system may be integrated in the design. The monitoring circuits may provide the signals necessary to actively compensate for changes in parameters of components. For example, a temperature reading may be used to calculate expected changes in, or to indicate previously measured values of, capacitance of the system allowing compensation by switching in other capacitors or tuning capacitors to maintain the desired capacitance over a range of temperatures. In embodiments, the RF amplifier switching waveforms may be adjusted to compensate for component value or load changes in the system. In some embodiments the changes in parameters of components may be compensated with active cooling, heating, active environment conditioning, and the like.

The parameter measurement circuitry may measure or monitor certain power, voltage, and current, signals in the system, and processors or control circuits may adjust certain settings or operating parameters based on those measurements. In addition the magnitude and phase of voltage and current signals, and the magnitude of the power signals, throughout the system may be accessed to measure or monitor the system performance. The measured signals referred to throughout this disclosure may be any combination of port parameter signals, as well as voltage signals, current signals, power signals, temperatures signals and the like. These parameters may be measured using analog or digital techniques, they may be sampled and processed, and they may be digitized or converted using a number of known analog and digital processing techniques. In embodiments, preset values of certain measured quantities are loaded in a system controller or memory location and used in various feedback and control loops. In embodiments, any combination of measured, monitored, and/or preset signals may be used in feedback circuits or systems to control the operation of the resonators and/or the system.

Adjustment algorithms may be used to adjust the frequency, Q, and/or impedance of the magnetic resonators. The algorithms may take as inputs reference signals related to the degree of deviation from a desired operating point for the system and may output correction or control signals related to that deviation that control variable or tunable elements of the system to bring the system back towards the desired operating point or points. The reference signals for the magnetic resonators may be acquired while the resonators are exchanging power in a wireless power transmission system, or they may be switched out of the circuit during system operation. Corrections to the system may be applied or performed continuously, periodically, upon a threshold crossing, digitally, using analog methods, and the like.

In embodiments, lossy extraneous materials and objects may introduce potential reductions in efficiencies by absorbing the magnetic and/or electric energy of the resonators of the wireless power transmission system. Those impacts may be mitigated in various embodiments by positioning resonators to minimize the effects of the lossy extraneous materials and objects and by placing structural field shaping elements (e.g., conductive structures, plates and sheets, magnetic material structures, plates and sheets, and combinations thereof) to minimize their effect.

One way to reduce the impact of lossy materials on a resonator is to use high-conductivity materials, magnetic materials, or combinations thereof to shape the resonator fields such that they avoid the lossy objects. In an exemplary embodiment, a layered structure of high-conductivity material and magnetic material may tailor, shape, direct, reorient, etc. the resonator's electromagnetic fields so that they avoid lossy objects in their vicinity by deflecting the fields. FIG. 2D shows a top view of a resonator with a sheet of conductor 226 below the magnetic material that may be used to tailor the fields of the resonator so that they avoid lossy objects that may be below the sheet of conductor 226. The layer or sheet of good 226 conductor may comprise any high conductivity materials such as copper, silver, aluminum, as may be most appropriate for a given application. In certain embodiments, the layer or sheet of good conductor is thicker than the skin depth of the conductor at the resonator operating frequency. The conductor sheet may be preferably larger than the size of the resonator, extending beyond the physical extent of the resonator.

In environments and systems where the amount of power being transmitted could present a safety hazard to a person or animal that may intrude into the active field volume, safety measures may be included in the system. In embodiments where power levels require particularized safety measures, the packaging, structure, materials, and the like of the resonators may be designed to provide a spacing or “keep away” zone from the conducting loops in the magnetic resonator. To provide further protection, high-Q resonators and power and control circuitry may be located in enclosures that confine high voltages or currents to within the enclosure, that protect the resonators and electrical components from weather, moisture, sand, dust, and other external elements, as well as from impacts, vibrations, scrapes, explosions, and other types of mechanical shock. Such enclosures call for attention to various factors such as thermal dissipation to maintain an acceptable operating temperature range for the electrical components and the resonator. In embodiments, enclosure may be constructed of non-lossy materials such as composites, plastics, wood, concrete, and the like and may be used to provide a minimum distance from lossy objects to the resonator components. A minimum separation distance from lossy objects or environments which may include metal objects, salt water, oil and the like, may improve the efficiency of wireless energy transfer. In embodiments, a “keep away” zone may be used to increase the perturbed Q of a resonator or system of resonators. In embodiments a minimum separation distance may provide for a more reliable or more constant operating parameters of the resonators.

In embodiments, resonators and their respective sensor and control circuitry may have various levels of integration with other electronic and control systems and subsystems. In some embodiments the power and control circuitry and the device resonators are completely separate modules or enclosures with minimal integration to existing systems, providing a power output and a control and diagnostics interface. In some embodiments a device is configured to house a resonator and circuit assembly in a cavity inside the enclosure, or integrated into the housing or enclosure of the device.

Communication in a Wireless Energy Transfer System

Communication of information between resonators may be implemented using in-band or out-of-band communications or communications channels. If at least some part of a magnetic resonator used to exchange power is also used to exchange information, and the carrier frequency of the information exchange is close to the resonant frequency used in the power exchange, we refer to that communication as in-band. Any other type of communication between magnetic resonators is referred to as out-of-band. An out-of-band communication channel may use an antenna and a signaling protocol that is separated from the energy transfer resonator and magnetic fields. An out-of-band communication channel may use or be based on Bluetooth, WiFi, Zigbee, NFC technology and the like.

Communication between resonators may be used to coordinate the wireless energy transfer or to adjust the parameters of a wireless energy transfer system, to identify and authenticate available power sources and devices, to optimize efficiency, power delivery, and the like, to track and bill energy preferences, usage, and the like, and to monitor system performance, battery condition, vehicle health, extraneous objects, also referred to as foreign objects, and the like. Methods for designating and verifying resonators for energy transfer may be different when in-band and out-of-band communication channels are used because the distance over which communication signals may be exchanged using out-of-band techniques may greatly exceed the distance over which the power signals may be exchanged. Also, the bandwidth of out-of-band communication signals may be larger than in-band communication signals. This difference in communication range and capability may affect the coordination of the wireless energy transfer system. For example, the number of resonators that may be addressed using out-of-band communication may be very large and communicating resonators may be farther apart than the distance over which they may efficiently exchange energy.

In some embodiments all of the signaling and communication may be performed using an in-band communication channel and the signals may be modulated on the fields used for energy transfer. In other embodiments, in-band communication may use substantially the same frequency spectrum as is used for energy transfer, but communication may occur while useful amounts of energy are not being transmitted. Using only the in-band communication channel may be preferable if separate or multiple verification steps are problematic, because the range of the communication may be limited to the same range as the power exchange or because the information arrives as a modulation on the power signal itself. In some embodiments however, a separate out-of-band communication channel may be more desirable. For example, an out-of-band communication channel may be less expensive to implement and may support higher data rates. An out-of-band communication channel may support longer distance communication, allowing resonator discovery and power system mapping. An out-of-band communication channel may operate regardless of whether or not power transfer is taking place and may occur without disruption of the power transfer.

Wireless Power Repeater Resonators

A wireless power transfer system may incorporate a repeater resonator configured to exchange energy with one or more source resonators, device resonators, or additional repeater resonators. A repeater resonator may be used to extend the range of wireless power transfer. A repeater resonator may be used to change, distribute, concentrate, enhance, and the like, the magnetic field generated by a source. A repeater resonator may be used to guide magnetic fields of a source resonator around lossy and/or metallic objects that might otherwise block the magnetic field. A repeater resonator may be used to eliminate or reduce areas of low power transfer, or areas of low magnetic field around a source. A repeater resonator may be used to improve the coupling efficiency between a source and a target device resonator or resonators, and may be used to improve the coupling between resonators with different orientations, or whose dipole moments are not favorably aligned.

An oscillating magnetic field produced by a source magnetic resonator can cause electrical currents in the conductor part of the repeater resonator. These electrical currents may create their own magnetic field as they oscillate in the resonator thereby extending or changing the magnetic field area or the magnetic field distribution of the source.

In embodiments, a repeater resonator may operate as a source for one or more device resonators. In other embodiments, a device resonator may simultaneously receive a magnetic field and repeat a magnetic field. In still other embodiments, a resonator may alternate between operating as a source resonator, device resonator or repeater resonator. The alternation may be achieved through time multiplexing, frequency multiplexing, self-tuning, or through a centralized control algorithm. In embodiments, multiple repeater resonators may be positioned in an area and tuned in and out of resonance to achieve a spatially varying magnetic field. In embodiments, a local area of strong magnetic field may be created by an array of resonators, and the positioned of the strong field area may be moved around by changing electrical components or operating characteristics of the resonators in the array.

In embodiments a repeater resonator may be a capacitively loaded loop magnetic resonator. In embodiments a repeater resonator may be a capacitively loaded loop magnetic resonator wrapper around magnetic material. In embodiments the repeater resonator may be tuned to have a resonant frequency that is substantially equal to that of the frequency of a source or device or at least one other repeater resonator with which the repeater resonator is designed to interact or couple. In other embodiments the repeater resonator may be detuned to have a resonant frequency that is substantially greater than, or substantially less than the frequency of a source or device or at least one other repeater resonator with which the repeater resonator is designed to interact or couple. Preferably, the repeater resonator may be a high-Q magnetic resonator with an intrinsic quality factor, Qᵣ, of 100 or more. In some embodiments the repeater resonator may have quality factor of less than 100. In some embodiments, \sqrt{QₛQ_{d}}>100. In other embodiments, \sqrt{Q_{d}Qᵣ}>100. In still other embodiments, \sqrt{Qᵣ₁Qᵣ₂}>100.

In embodiments, the repeater resonator may include only the inductive and capacitive components that comprise the resonator without any additional circuitry, for connecting to sources, loads, controllers, monitors, control circuitry and the like. In some embodiments the repeater resonator may include additional control circuitry, tuning circuitry, measurement circuitry, or monitoring circuitry. Additional circuitry may be used to monitor the voltages, currents, phase, inductance, capacitance, and the like of the repeater resonator. The measured parameters of the repeater resonator may be used to adjust or tune the repeater resonator. A controller or a microcontroller may be used by the repeater resonator to actively adjust the capacitance, resonant frequency, inductance, resistance, and the like of the repeater resonator. A tunable repeater resonator may be necessary to prevent the repeater resonator from exceeding its voltage, current, temperature, or power limits. A repeater resonator may for example detune its resonant frequency to reduce the amount of power transferred to the repeater resonator, or to modulate or control how much power is transferred to other devices or resonators that couple to the repeater resonator.

In some embodiments the power and control circuitry of the repeater resonators may be powered by the energy captured by the repeater resonator. The repeater resonator may include AC to DC, AC to AC, or DC to DC converters and regulators to provide power to the control or monitoring circuitry. In some embodiments the repeater resonator may include an additional energy storage component such as a battery or a super capacitor to supply power to the power and control circuitry during momentary or extended periods of wireless power transfer interruptions. The battery, super capacitor, or other power storage component may be periodically or continuously recharged during normal operation when the repeater resonator is within range of any wireless power source.

In some embodiments the repeater resonator may include communication or signaling capability such as WiFi, Bluetooth, near field, and the like that may be used to coordinate power transfer from a source or multiple sources to a specific location or device or to multiple locations or devices. Repeater resonators spread across a location may be signaled to selectively tune or detune from a specific resonant frequency to extend the magnetic field from a source to a specific location, area, or device. Multiple repeater resonators may be used to selectively tune, or detune, or relay power from a source to specific areas or devices.

The repeater resonators may include a device into which some, most, or all of the energy transferred or captured from the source to the repeater resonator may be available for use. The repeater resonator may provide power to one or more electric or electronic devices while relaying or extending the range of the source. In some embodiments low power consumption devices such as lights, LEDs, displays, sensors, and the like may be part of the repeater resonator.

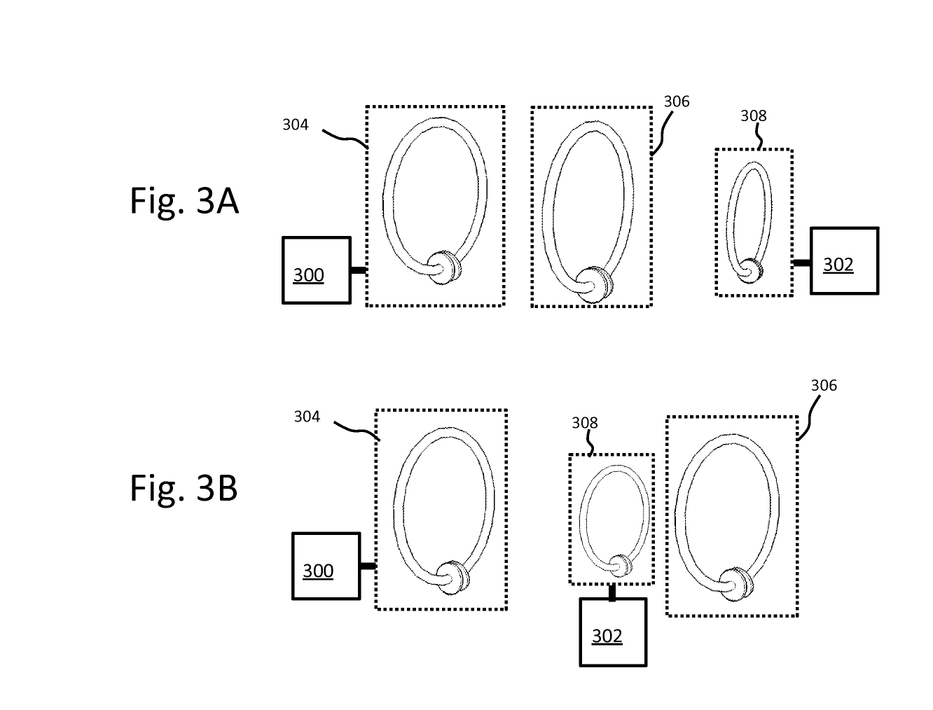

Several possible usage configurations are shown in FIGS. 3-5. The figures show example arrangements of a wireless power transfer system that includes a source 304 resonator coupled to a power source 300, a device resonator 308 coupled to a device 302, and a repeater resonator 306. In some embodiments, a repeater resonator may be used between the source and the device resonator to extend the range of the source as shown in FIG. 3A. In some embodiments the repeater resonator may be positioned after, and further away from the source than the device resonator as shown in FIG. 3B. For the configuration shown in FIG. 3B more efficient power transfer between the source and the device may be possible compared to if no repeater resonator was used. In embodiments of the configuration shown in FIG. 3B it may be preferable for the repeater resonator to be larger than the device resonator.

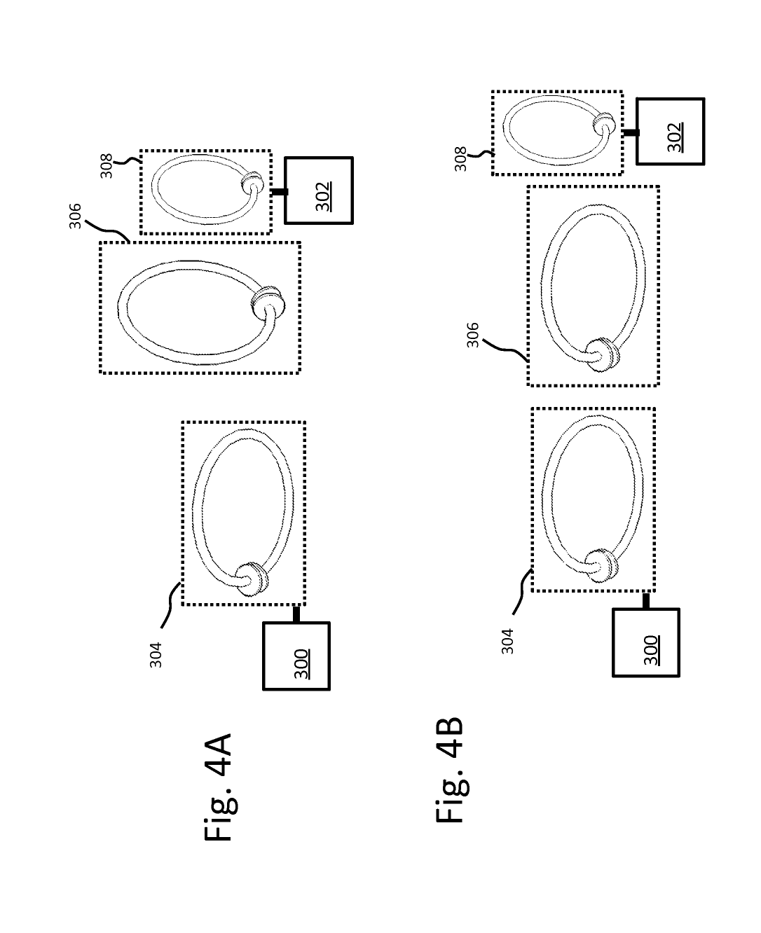

In some embodiments a repeater resonator may be used to improve coupling between non-coaxial resonators or resonators whose dipole moments are not aligned for high coupling factors or energy transfer efficiencies. For example, a repeater resonator may be used to enhance coupling between a source and a device resonator that are not coaxially aligned by placing the repeater resonator between the source and device aligning it with the device resonator as shown in FIG. 4A or aligning with the source resonator as shown in FIG. 4B.

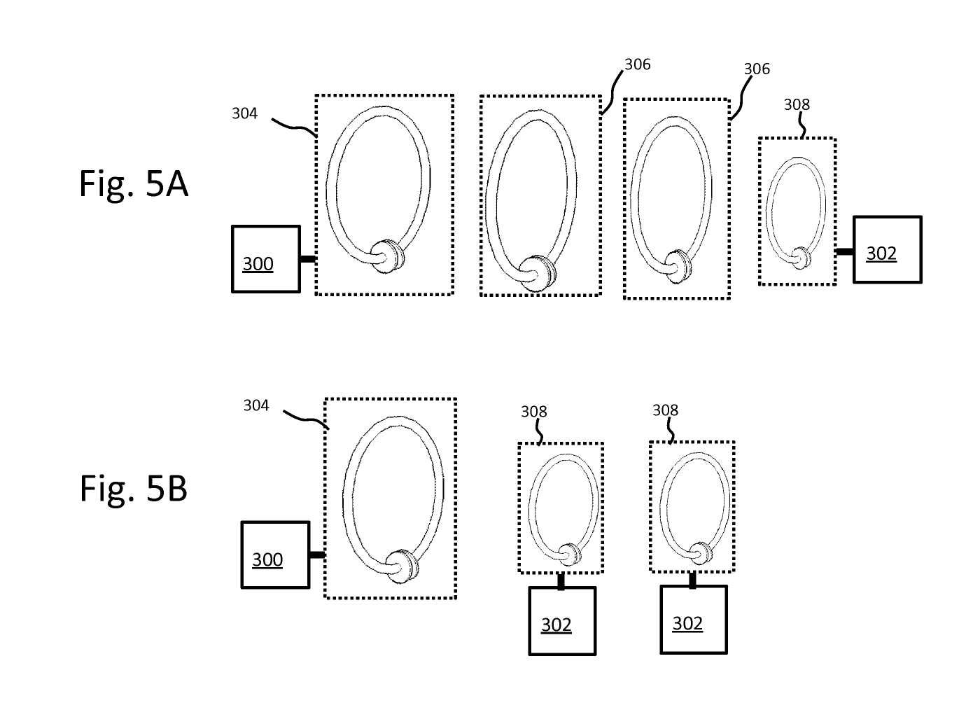

In some embodiments multiple repeater resonators may be used to extend the wireless power transfer into multiple directions or multiple repeater resonators may one after another to extend the power transfer distance as shown in FIG. 5A. In some embodiments, a device resonator that is connected to load or electronic device may operate simultaneously, or alternately as a repeater resonator for another device, repeater resonator, or device resonator as shown in FIG. 5B. Note that there is no theoretical limit to the number of resonators that may be used in a given system or operating scenario, but there may be practical issues that make a certain number of resonators a preferred embodiment. For example, system cost considerations may constrain the number of resonators that may be used in a certain application. System size or integration considerations may constrain the size of resonators used in certain applications.

In some embodiments the repeater resonator may have dimensions, size, or configuration that is the same as the source or device resonators. In some embodiments the repeater resonator may have dimensions, size, or configuration that is different than the source or device resonators. The repeater resonator may have a characteristic size that is larger than the device resonator or larger than the source resonator, or larger than both. A larger repeater resonator may improve the coupling between the source and the repeater resonator at a larger separation distance between the source and the device.

In some embodiments two or more repeater resonators may be used in a wireless power transfer system. In some embodiments two or more repeater resonators with two or more sources or devices may be used.

Repeater Resonator Modes of Operation

A repeater resonator may be used to enhance or improve wireless power transfer from a source to one or more resonators built into electronics that may be powered or charged on top of, next to, or inside of tables, desks, shelves, cabinets, beds, television stands, and other furniture, structures, and/or containers. A repeater resonator may be used to generate an energized surface, volume, or area on or next to furniture, structures, and/or containers, without requiring any wired electrical connections to a power source. A repeater resonator may be used to improve the coupling and wireless power transfer between a source that may be outside of the furniture, structures, and/or containers, and one or more devices in the vicinity of the furniture, structures, and/or containers.

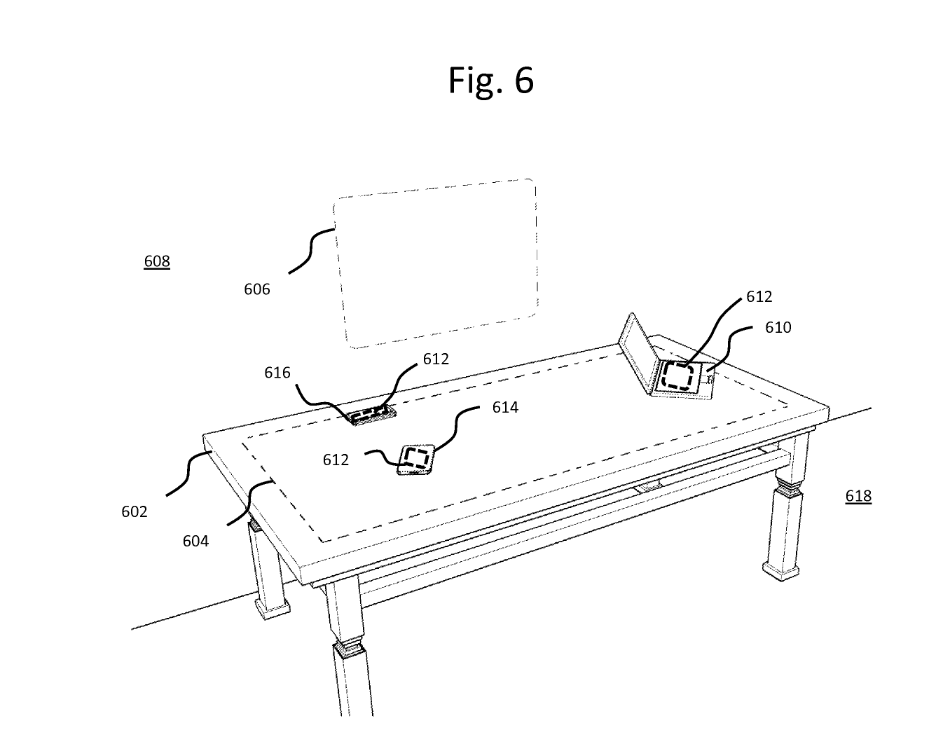

In one exemplary embodiment depicted in FIG. 6, a repeater resonator 604 may be used with a table surface 602 to energize the top of the table for powering or recharging of electronic devices 610, 616, 614 that have integrated or attached device resonators 612. The repeater resonator 604 may be used to improve the wireless power transfer from the source 606 to the device resonators 612.

In some embodiments the power source and source resonator may be built into walls, floors, dividers, ceilings, partitions, wall coverings, floor coverings, and the like. A piece of furniture comprising a repeater resonator may be energized by positioning the furniture and the repeater resonator close to the wall, floor, ceiling, partition, wall covering, floor covering, and the like that includes the power source and source resonator. When close to the source resonator, and configured to have substantially the same resonant frequency as the source resonator, the repeater resonator may couple to the source resonator via oscillating magnetic fields generated by the source. The oscillating magnetic fields produce oscillating currents in the conductor loops of the repeater resonator generating an oscillating magnetic field, thereby extending, expanding, reorienting, concentrating, or changing the range or direction of the magnetic field generated by the power source and source resonator alone. The furniture including the repeater resonator may be effectively “plugged in” or energized and capable of providing wireless power to devices on top, below, or next to the furniture by placing the furniture next to the wall, floor, ceiling, etc. housing the power source and source resonator without requiring any physical wires or wired electrical connections between the furniture and the power source and source resonator. Wireless power from the repeater resonator may be supplied to device resonators and electronic devices in the vicinity of the repeater resonator. Power sources may include, but are not limited to, electrical outlets, the electric grid, generators, solar panels, fuel cells, wind turbines, batteries, super-capacitors and the like.

In embodiments, a repeater resonator may enhance the coupling and the efficiency of wireless power transfer to device resonators of small characteristic size, non-optimal orientation, and/or large separation from a source resonator. The efficiency of wireless power transfer may be inversely proportional to the separation distance between a source and device resonator, and may be described relative to the characteristic size of the smaller of the source or device resonators. For example, a device resonator designed to be integrated into a mobile device such as a smart phone 612, with a characteristic size of approximately 5 cm, may be much smaller than a source resonator 606, designed to be mounted on a wall, with a characteristic size of 50 cm, and the separation between these two resonators may be 60 cm or more, or approximately twelve or more characteristic sizes of the device resonator, resulting in low power transfer efficiency. However, if a 50 cm×100 cm repeater resonator is integrated into a table, as shown in FIG. 6, the separation between the source and the repeater may be approximately one characteristic size of the source resonator, so that the efficiency of power transfer from the source to the repeater may be high. Likewise, the smart phone device resonator placed on top of the table or the repeater resonator, may have a separation distance of less than one characteristic size of the device resonator resulting in high efficiency of power transfer between the repeater resonator and the device resonator. While the total transfer efficiency between the source and device must take into account both of these coupling mechanisms, from the source to the repeater and from the repeater to the device, the use of a repeater resonator may provide for improved overall efficiency between the source and device resonators.

In embodiments, the repeater resonator may enhance the coupling and the efficiency of wireless power transfer between a source and a device if the dipole moments of the source and device resonators are not aligned or are positioned in non-favorable or non-optimal orientations. In the exemplary system configuration depicted in FIG. 6, a capacitively loaded loop source resonator integrated into the wall may have a dipole moment that is normal to the plane of the wall. Flat devices, such as mobile handsets, computers, and the like, that normally rest on a flat surface may comprise device resonators with dipole moments that are normal to the plane of the table, such as when the capacitively loaded loop resonators are integrated into one or more of the larger faces of the devices such as the back of a mobile handset or the bottom of a laptop. Such relative orientations may yield coupling and the power transfer efficiencies that are lower than if the dipole moments of the source and device resonators were in the same plane, for example. A repeater resonator that has its dipole moment aligned with that of the dipole moment of the device resonators, as shown in FIG. 6, may increase the overall efficiency of wireless power transfer between the source and device because the large size of the repeater resonator may provide for strong coupling between the source resonator even though the dipole moments of the two resonators are orthogonal, while the orientation of the repeater resonator is favorable for coupling to the device resonator.

In the exemplary embodiment shown in FIG. 6, the direct power transfer efficiency between a 50 cm×50 cm source resonator 606 mounted on the wall and a smart-phone sized device resonator 612 lying on top of the table, and approximately 60 cm away from the center of the source resonator, with no repeater resonator present, was calculated to be approximately 19%. Adding a 50 cm×100 cm repeater resonator as shown, and maintaining the relative position and orientation of the source and device resonators improved the coupling efficiency from the source resonator to the device resonator to approximately 60%. In this one example, the coupling efficiency from the source resonator to the repeater resonator was approximately 85% and the coupling efficiency from the repeater resonator to the device resonator was approximately 70%. Note that in this exemplary embodiment, the improvement is due both to the size and the orientation of the repeater resonator.

In embodiments of systems that use a repeater resonator such as the exemplary system depicted in FIG. 6, the repeater resonator may be integrated into the top surface of the table or furniture. In other embodiments the repeater resonator may be attached or configured to attach below the table surface. In other embodiments, the repeater resonator may be integrated in the table legs, panels, or structural supports. Repeater resonators may be integrated in table shelves, drawers, leaves, supports, and the like. In yet other embodiments the repeater resonator may be integrated into a mat, pad, cloth, potholder, and the like, that can be placed on top of a table surface. Repeater resonators may be integrated into items such as bowls, lamps, dishes, picture frames, books, tchotchkes, candle sticks, hot plates, flower arrangements, baskets, and the like.

In embodiments the repeater resonator may use a core of magnetic material or use a form of magnetic material and may use conducting surfaces to shape the field of the repeater resonator to improve coupling between the device and source resonators or to shield the repeater resonators from lossy objects that may be part of the furniture, structures, or containers.

In embodiments, in addition to the exemplary table described above, repeater resonators may be built into chairs, couches, bookshelves, carts, lamps, rugs, carpets, mats, throws, picture frames, desks, counters, closets, doors, windows, stands, islands, cabinets, hutches, fans, shades, shutters, curtains, footstools, and the like.

In embodiments, the repeater resonator may have power and control circuitry that may tune the resonator or may control and monitor any number of voltages, currents, phases, temperature, fields, and the like within the resonator and outside the resonator. The repeater resonator and the power and control circuitry may be configured to provide one or more modes of operation. The mode of operation of the repeater resonator may be configured to act only as repeater resonator. In other embodiments the mode of operation of the repeater resonator may be configured to act as a repeater resonator and/or as a source resonator. The repeater resonator may have an optional power cable or connector allowing connection to a power source such as an electrical outlet providing an energy source for the amplifiers of the power and control circuits for driving the repeater resonator turning it into a source if, for example, a source resonator is not functioning or is not in the vicinity of the furniture. In other embodiments the repeater resonator may have a third mode of operation in which it may also act as a device resonator providing a connection or a plug for connecting electrical or electronic devices to receive DC or AC power captured by the repeater resonator. In embodiments these modes be selected by the user or may be automatically selected by the power and control circuitry of the repeater resonator based on the availability of a source magnetic field, electrical power connection, or a device connection.

In embodiments the repeater resonator may be designed to operate with any number of source resonators that are integrated into walls, floors, other objects or structures. The repeater resonators may be configured to operate with sources that are retrofitted, hung, or suspended permanently or temporarily from walls, furniture, ceilings and the like.

Although the use of a repeater resonator with furniture has been described with the an exemplary embodiment depicting a table and table top devices it should be clear to those skilled in the art that the same configurations and designs may be used and deployed in a number of similar configurations, furniture articles, and devices. For example, a repeater resonator may be integrated into a television or a media stand or a cabinet such that when the cabinet or stand is placed close to a source the repeater resonator is able to transfer enough energy to power or recharge electronic devices on the stand or cabinet such as a television, movie players, remote controls, speakers, and the like.

In embodiments the repeater resonator may be integrated into a bucket or chest that can be used to store electronics, electronic toys, remote controls, game controllers, and the like. When the chest or bucket is positioned close to a source the repeater resonator may enhance power transfer from the source to the devices inside the chest or bucket with built in device resonators to allow recharging of the batteries.

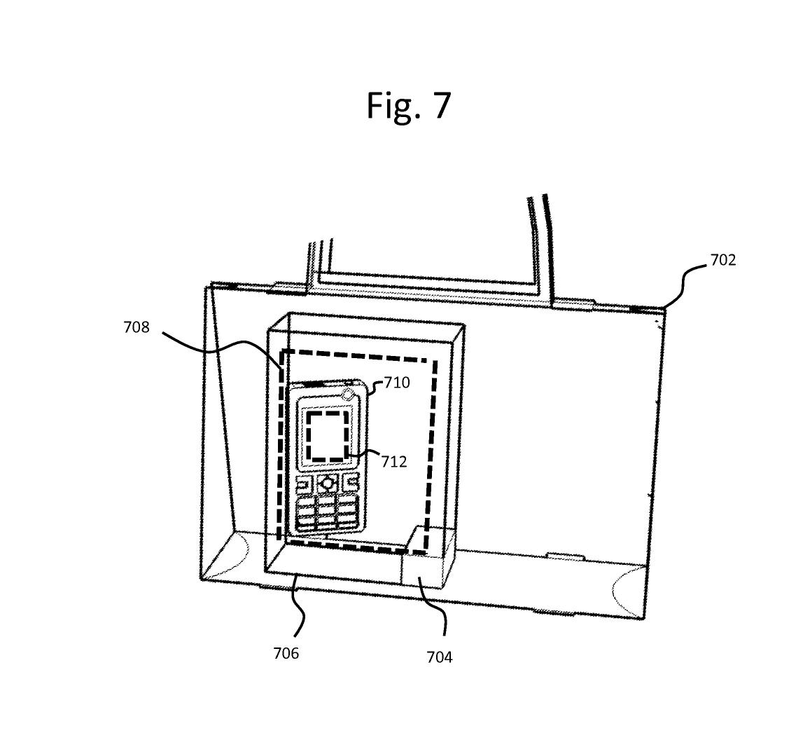

Another exemplary embodiment showing the use of a repeater resonator is depicted in FIG. 7. In this embodiment the repeater resonator may be used in three different modes of operation depending on the usage and state of the power sources and consumers in the arrangement. The figure shows a handbag 702 that is depicted as transparent to show internal components. In this exemplary embodiment, there may be a separate bag, satchel, pocket, or compartment 706 inside the bag 702 that may be used for storage or carrying of electronic devices 710 such as cell-phones, MP3 players, cameras, computers, e-readers, iPads, netbooks, and the like. The compartment may be fitted with a resonator 708 that may be operated in at least three modes of operation. In one mode, the resonator 708 may be coupled to power and control circuitry that may include rechargeable or replaceable batteries or battery packs or other types of portable power supplies 704 and may operate as a wireless power source for wirelessly recharging or powering the electronic devices located in the handbag 702 or the handbag compartment 706. In this configuration and setting, the bag and the compartment may be used as a portable, wireless recharging or power station for electronics.

The resonator 708 may also be used as a repeater resonator extending the wireless power transfer from an external source to improve coupling and wireless power transfer efficiency between the external source and source resonator (not shown) and the device resonators 712 of the device 710 inside the bag or the compartment. The repeater resonator may be larger than the device resonators inside the bag or the compartment and may have improved coupling to the source.

In another mode, the resonator may be used as a repeater resonator that both supplies power to electronic devices and to a portable power supply used in a wireless power source. When positioned close to an external source or source resonator the captured wireless energy may be used by a repeater resonator to charge the battery 704 or to recharge the portable energy source of the compartment 706 allowing its future use as a source resonator. The whole bag with the devices may be placed near a source resonator allowing both recharging of the compartment battery 704 and the batteries of the devices 710 inside the compartment 706 or the bag 702.

In embodiments the compartment may be built into a bag or container or may be an additional or independent compartment that may be placed into any bag or storage enclosure such as a backpack, purse, shopping bag, luggage, device cases, and the like.

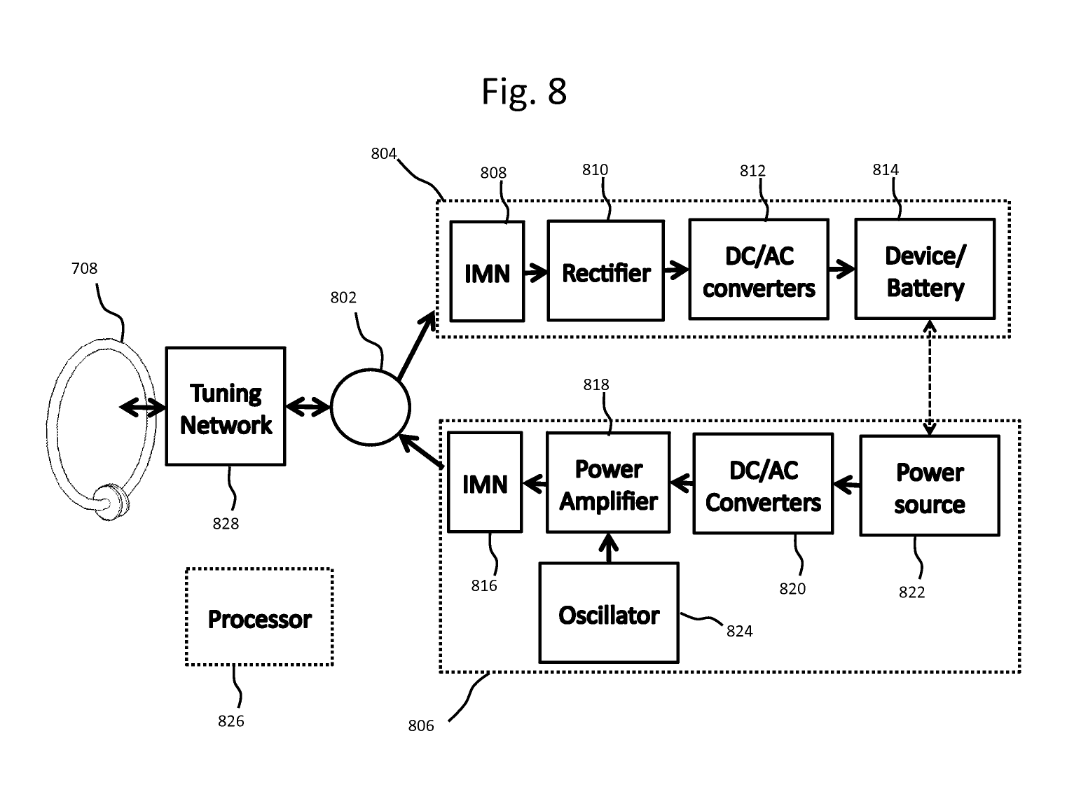

In embodiments, the resonator may comprise switches that couple the power and control circuitry into and out of the resonator circuit so that the resonator may be configured only as a source resonator, only as a repeater resonator, or simultaneously or intermittently as any combination of a source, device and repeater resonator. An exemplary block diagram of a circuit configuration capable of controlling and switching a resonator between the three modes of operation is shown in FIG. 8. In this configuration a capacitively loaded conducting loop 708 is coupled to a tuning network 828 to form a resonator. The tuning network 828 may be used to set, configure, or modify the resonant frequency, impedance, resistance, and the like of the resonator. The resonator may be coupled to a switching element 802, comprising any number of solid state switches, relays, and the like, that may couple or connect the resonator to either one of at least two circuitry branches, a device circuit branch 804 or a source circuit branch 806, or may be used to disconnect from any of the at least two circuit branches during an inactive state or for certain repeater modes of operation. A device circuit branch 804 may be used when the resonator is operating in a repeater or device mode. A device circuit branch 804 may convert electrical energy of the resonator to specific DC or AC voltages required by a device, load, battery, and the like and may comprise an impedance matching network 808, a rectifier 810, DC to DC or DC to AC converters 810, and any devices, loads, or batteries requiring power 814. A device circuit branch may be active during a device mode of operation and/or during a repeater mode of operation. During a repeater mode of operation, a device circuit branch may be configured to drain some power from the resonator to power or charge a load while the resonator is simultaneously repeating the oscillating magnetic fields from an external source to another resonator.

A source circuit branch 806 may be used during repeater and/or source mode of operation of the resonator. A source circuit branch 806 may provide oscillating electrical energy to drive the resonator to generate oscillating magnetic fields that may be used to wirelessly transfer power to other resonators. A source circuit branch may comprise a power source 822, which may be the same energy storage device such as a battery that is charged during a device mode operation of the resonator. A source circuit branch may comprise DC to AC or AC to AC converters 820 to convert the voltages of a power source to produce oscillating voltages that may be used to drive the resonator through an impedance matching network 816. A source circuit branch may be active during a source mode of operation and/or during a repeater mode of operation of the resonator allowing wireless power transfer from the power source 822 to other resonators. During a repeater mode of operation, a source circuit branch may be used to amplify or supplement power to the resonator. During a repeater mode of operation, the external magnetic field may be too weak to allow the repeater resonator to transfer or repeat a strong enough field to power or charge a device. The power from the power source 822 may be used to supplement the oscillating voltages induced in the resonator 708 from the external magnetic field to generate a stronger oscillating magnetic field that may be sufficient to power or charge other devices.

In some instances, both the device and source circuit branches may be disconnected from the resonator. During a repeater mode of operation the resonator may be tuned to an appropriate fixed frequency and impedance and may operate in a passive manner. That is, in a manner where the component values in the capacitively loaded conducting loop and tuning network are not actively controlled. In some embodiments, a device circuit branch may require activation and connection during a repeater mode of operation to power control and measurement circuitry used to monitor, configure, and tune the resonator.

In embodiments, the power and control circuitry of a resonator enabled to operate in multiple modes may include a processor 826 and measurement circuitry, such as analog to digital converters and the like, in any of the components or sub-blocks of the circuitry, to monitor the operating characteristics of the resonator and circuitry. The operating characteristics of the resonator may be interpreted and processed by the processor to tune or control parameters of the circuits or to switch between modes of operation. Voltage, current, and power sensors in the resonator, for example, may be used to determine if the resonator is within a range of an external magnetic field, or if a device is present, to determine which mode of operation and which circuit branch to activate.

Wireless Energy Distribution System

Wireless energy may be distributed over an area using repeater resonators. In embodiments a whole area such as a floor, ceiling, wall, table top, surface, shelf, body, area, and the like may be wirelessly energized by positioning or tiling a series of repeater resonators and source resonators over the area. In some embodiments, a group of objects comprising resonators may share power amongst themselves, and power may be wireless transmitted to and/or through various objects in the group. In an exemplary embodiment, a number of vehicles may be parked in an area and only some of the vehicles may be positioned to receive wireless power directly from a source resonator. In such embodiments, certain vehicles may retransmit and/or repeat some of the wireless power to vehicles that are not parked in positions to receive wireless power directly from a source. In embodiments, power supplied by a vehicle charging source may use repeaters to transmit power into the vehicles to power devices such as cell phones, computers, displays, navigation devices, communication devices, and the like. In some embodiments, a vehicle parked over a wireless power source may vary the ratio of the amount of power it receives and the amount of power it retransmits or repeats to other nearby vehicles. In embodiments, wireless power may be transmitted from one source to device after device and so on, in a daisy chained fashion. In embodiments, certain devices may be able to self determine how much power that receive and how much they pass on. In embodiments, power distribution amongst various devices and/or repeaters may be controlled by a master node or a centralized controller.

Some repeater resonators may be positioned in proximity to one or more source resonators. The energy from the source may be transferred from the sources to the repeaters, and from those repeaters to other repeaters, and to other repeaters, and so on. Therefore energy may be wirelessly delivered to a relatively large area with the use of small sized sources being the only components that require physical or wired access to an external energy source.

In embodiments the energy distribution over an area using a plurality of repeater resonators and at least one source has many potential advantages including in ease of installation, configurability, control, efficiency, adaptability, cost, and the like. For example, using a plurality of repeater resonators allows easier installation since an area may be covered by the repeater resonators in small increments, without requiring connections or wiring between the repeaters or the source and repeaters. Likewise, a plurality of smaller repeater coils allows a greater flexibility of placement allowing the arrangement and coverage of an area with an irregular shape. Furthermore, the repeater resonators may be easily moved or repositioned to change the magnetic field distribution within an area. In some embodiments the repeaters and the sources may be tunable or adjustable allowing the repeater resonators to be tuned or detuned from the source resonators and allowing a dynamic reconfiguration of energy transfer or magnetic field distribution within the area covered by the repeaters without physically moving components of the system.

For example, in one embodiment, repeater resonators and wireless energy sources may be incorporated or integrated into flooring. In embodiments, resonator may be integrated into flooring or flooring products such as carpet tiles to provide wireless power to an area, room, specific location, multiple locations and the like. Repeater resonators, source resonators, or device resonators may be integrated into the flooring and distribute wireless power from one or more sources to one more devices on the floor via a series of repeater resonators that transfer the energy from the source over an area of the floor.

It is to be understood that the techniques, system design, and methods may be applied to many flooring types, shapes, and materials including carpet, ceramic tiles, wood boards, wood panels and the like. For each type of material those skilled in the art will recognize that different techniques may be used to integrate or attach the resonators to the flooring material. For example, for carpet tiles the resonators may be sown in or glued on the underside while for ceramic tiles integration of tiles may require a slurry type material, epoxy, plaster, and the like. In some embodiments the resonators may not be integrated into the flooring material but placed under the flooring or on the flooring. The resonators may, for example, come prepackaged in padding material that is placed under the flooring. In some embodiments a series or an array or pattern of resonators, which may include source, device, and repeater resonators, may be integrated in to a large piece of material or flooring which may be cut or trimmed to size. The larger material may be trimmed in between the individual resonators without disrupting or damaging the operation of the cut piece.

Returning now to the example of the wireless floor embodiment comprising individual carpet tiles, the individual flooring tiles may be wireless power enabled by integrating or inserting a magnetic resonator to the tile or under the tile. In embodiments resonator may comprise a loop or loops of a good conductor such as Litz wire and coupled to a capacitive element providing a specific resonant frequency which may be in the range of 10 KHz to 100 MHz. In embodiments the resonator may be a high-Q resonator with a quality factor greater than 100. Those skilled in the art will appreciate that the various designs, shaped, and methods for resonators such as planar resonators, capacitively loaded loop resonators, printed conductor loops, and the like described herein may be integrated or combined within a flooring tile or other flooring material.

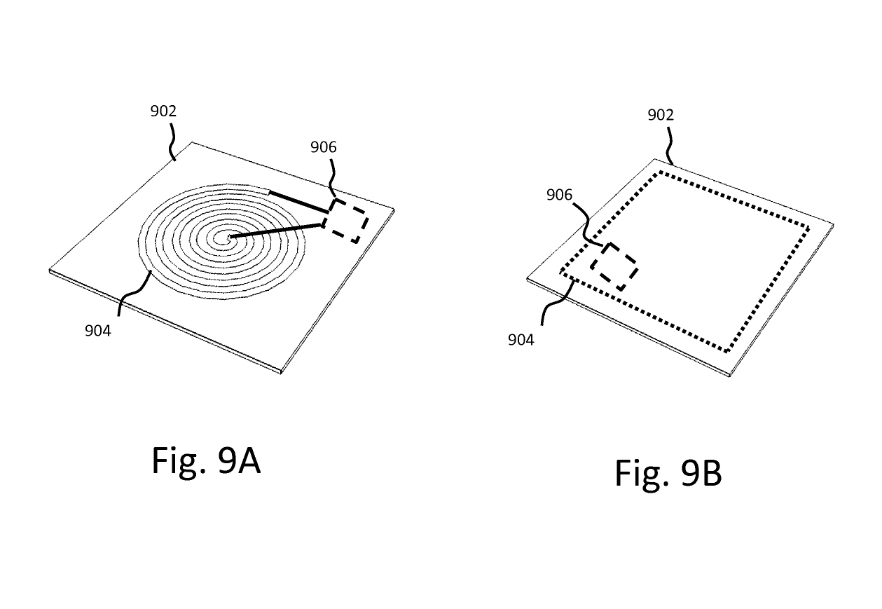

Example embodiments of a wireless power enabled floor tile are depicted in FIG. 9A and FIG. 9B. A floor tile 902 may include loops of an electrical conductor 904 that are wound within the perimeter of the tile. In embodiments the conductor 904 of the resonator may be coupled to additional electric or electronic components 906 such as capacitors, power and control circuitry, communication circuitry, and the like. In other embodiments the tile may include more than one resonator and more than one loop of conductors that may be arranged in an array or a deliberate pattern as described herein such as for example a series of multisized coils, a configurable size coil and the like.

In embodiments the coils and resonators integrated into the tiles may include magnetic material. Magnetic material may be used to construct planar resonator structures such those depicted in FIG. 2C or FIG. 2E. In embodiments the magnetic material may also be used for shielding of the coil of the resonator from lossy objects that may be under or around the flooring. In some embodiments the structures may further include a layer or sheet of a good electrical conductor under the magnetic material to increase the shielding capability of the magnetic material as described herein.

Tiles with a resonator may have various functionalities and capabilities depending on the control circuitry, communication circuitry, sensing circuitry, and the like that is coupled to the coil or resonator structure. In embodiments of a wireless power enabled flooring the system may include multiple types of wireless enabled tiles with different capabilities. One type of floor tile may comprise only a magnetic resonator and function as a fixed tuned repeater resonator that wirelessly transfers power from one resonator to another resonator without any direct or wired power source or wired power drain.

Another type of floor tile may comprise a resonator coupled to control electronics that may dynamically change or adjust the resonant frequency of the resonator by, for example, adjusting the capacitance, inductance, and the like of the resonator. The tile may further include an in-band or out-of-band communication capability such that it can exchange information with other communication enabled tiles. The tile may be then able to adjust its operating parameters such as resonant frequency in response to the received signals from the communication channel.

Another type of floor tile may comprise a resonator coupled to integrated sensors that may include temperature sensors, pressure sensors, inductive sensors, magnetic sensors, and the like. Some or all the power captured by the resonator may be used to wirelessly power the sensors and the resonator may function as a device or partially as a repeater.

Yet another type of wireless power enabled floor tile may comprise a resonator with power and control circuitry that may include an amplifier and a wired power connection for driving the resonator and function like a wireless power source. The features, functions, capabilities of each of the tiles may be chosen to satisfy specific design constraints and may feature any number of different combinations of resonators, power and control circuitry, amplifiers, sensors, communication capabilities and the like.

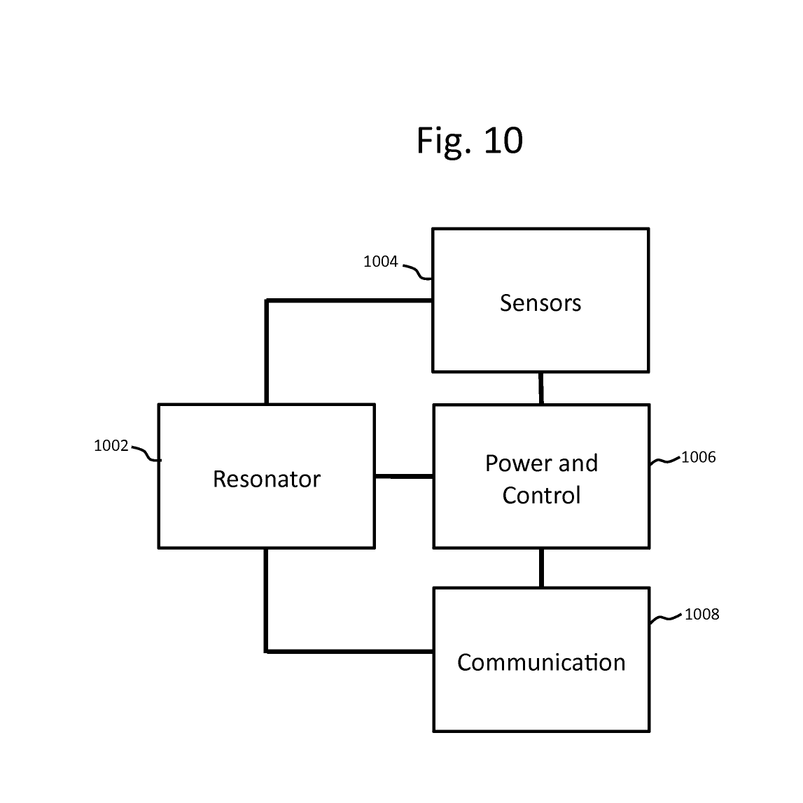

A block diagram of the components comprising a resonator tile are shown in FIG. 10. In a tile, a resonator 1002 may be optionally coupled to power and control circuitry 1006 to receive power and power devices or optional sensors 1004. Additional optional communication circuitry 1008 may be connected to the power and control circuitry and control the parameters of the resonator based on received signals.

Tiles and resonators with different features and capabilities may be used to construct a wireless energy transfer systems with various features and capabilities. One embodiment of a system may include sources and only fixed tuned repeater resonator tiles. Another system may comprise a mixture of fixed and tunable resonator tiles with communication capability. To illustrate some of the differences in system capabilities that may be achieved with different types of floor tiles we will describe example embodiments of a wireless floor system.

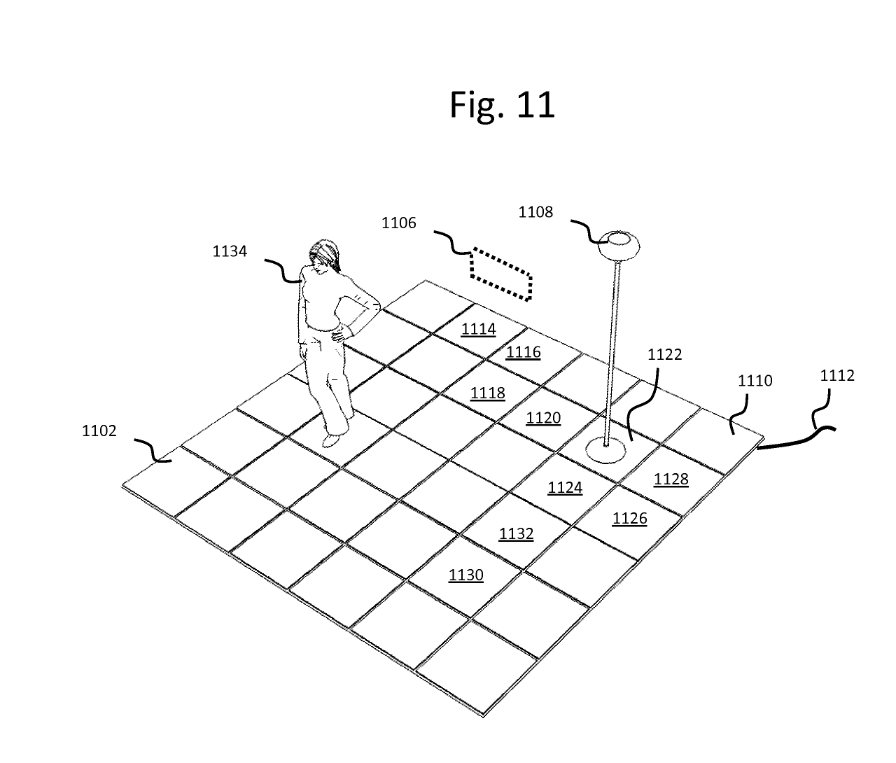

The first example embodiment of the wireless floor system may include a source and only fixed tuned repeater resonator tiles. In this first embodiment a plurality of fixed tuned resonator tiles may be arranged on a floor to transfer power from a source to an area or location over or next to the tiles and deliver wireless power to devices that may be placed on top of the tiles, below the tiles, or next to the tiles. The repeater resonators may be fixed tuned to a fixed frequency that may be close to the frequency of the source. An arrangement of the first example embodiment is shown in FIG. 11. The tiles 1102 are arranged in an array with at least one source resonator that may be integrated into a tile 1110 or attached to a wall 1106 and wired 1112 to a power source. Some repeater tiles may be positioned next to the source resonator and arranged to transfer the power from the source to a desired location via one or more additional repeater resonators.

Energy may be transferred to other tiles and resonators that are further away from the source resonators using tiles with repeater resonators which may be used to deliver power to devices, integrated or connected to its own device resonator and device power and control electronics that are placed on top or near the tiles. For example, power from the source resonator 1106 may be transferred wirelessly from the source 1106 to an interior area or interior tile 1122 via multiple repeater resonators 1114, 1116, 1118, 1120 that are between the interior tile 1122 and the source 1106. The interior tile 1122 may than transfer the power to a device such as a resonator built into the base of a lamp 1108. Tiles with repeater resonators may be positioned to extend the wireless energy transfer to a whole area of the floor allowing a device on top of the floor to be freely moved within the area. For example additional repeater resonator tiles 1124, 1126, 1128 may be positioned around the lamp 1108 to create a defined area of power (tiles 1114, 1116, 1118, 1120, 1122, 1124, 1126, 1128) over which the lamp may be placed to receive energy from the source via the repeater tiles. The defined area over which power is distributed may be changed by adding more repeater tiles in proximity to at least one other repeater or source tile. The tiles may be movable and configurable by the user to change the power distribution as needed or as the room configuration changes. Except a few tiles with source resonators which may need wired source or energy, each tile may be completely wireless and may be configured or moved by the user or consumer to adjust the wireless power flooring system.

A second embodiment of the wireless floor system may include a source and one or more tunable repeater resonator tiles. In embodiments the resonators in each or some of the tiles may include control circuitry allowing dynamic or periodic adjustment of the operating parameters of the resonator. In embodiments the control circuitry may change the resonant frequency of the resonator by adjusting a variable capacitor or a changing a bank of capacitors.

To obtain maximum efficiency of power transfer or to obtain a specific distribution of power transfer in the system of multiple wireless power enabled tiles it may be necessary to adjust the operating point of each resonator and each resonator may be tuned to a different operating point. For example, in some situations or applications the required power distribution in an array of tiles may be required to be non-uniform, with higher power required on one end of the array and lower power on the opposite end of the array. Such a distribution may be obtained, for example, by slightly detuning the frequency of the resonators from the resonant frequency of the system to distribute the wireless energy where it is needed.

For example, consider the array of tiles depicted in FIG. 11 comprising 36 tunable repeater resonator tiles with a single source resonator 1106. If only one device that requires power is placed on the floor, such as the lamp 1108, it may be inefficient to distribute the energy across every tile when the energy is needed in only one section of the floor tile array. In embodiments the tuning of individual tiles may be used to change the energy transfer distribution in the array. In the example of the single lamp device 1108, the repeater tiles that are not in direct path from the source resonator 1106 to the tile closes to the device 1122 may be completely or partially detuned from the frequency of the source. Detuning of the unused repeaters reduces the interaction of the resonators with the oscillating magnetic fields changing the distribution of the magnetic fields in the floor area. With tunable repeater tiles, a second device may be placed within the array of tiles or the lamp device 1108 is moved from its current location 1122 to another tile, say 1130, the magnetic field distribution in the area of the tiles may be changed by retuning tiles that are in the path from the source 1106 to the new location 1130.

In embodiments, to help coordinate the distribution of power and tuning of the resonators the resonator may include a communication capability. Each resonator may be capable of wirelessly communicating with one or more of its neighboring tiles or any one of the tiles to establish an appropriate magnetic field distribution for a specific device arrangement.

In embodiments the tuning or adjustment of the operating point of the individual resonators to generate a desired magnetic field distribution over the area covered by the tiles may be performed in a centralized manner from one source or one “command tile”. In such a configuration the central tile may gather the power requirements and the state of each resonator and each tile via wireless communication or in band communication of each tile and calculate the most appropriate operating point of each resonator for the desired power distribution or operating point of the system. The information may be communicated to each individual tile wirelessly by an additional wireless communication channel or by modulating the magnetic field used for power transfer. The power may be distributed or metered out using protocols similar to those used in communication systems. For example, there may be devices that get guaranteed power, while others get best effort power. Power may be distributed according to a greedy algorithm, or using a token system. Many protocols that have been adapted for sharing information network resources may be adapted for sharing wireless power resources.

In other embodiments the tuning or adjustment of the operating point of the individual resonators may be performed in a decentralized manner. Each tile may adjust the operating point of its resonator on its own based on the power requirements or state of the resonators of tiles in its near proximity.

In both centralized and decentralized arrangements any number of network based centralized and distributed routing protocols may be used. For example, each tile may be considered as a node in network and shortest path, quickest path, redundant path, and the like, algorithms may be used to determine the most appropriate tuning of resonators to achieve power delivery to one or more devices.

In embodiments various centralized and decentralized routing algorithms may be used to tune and detune resonators of a system to route power via repeater resonators around lossy objects. If an object comprising lossy material is placed on some of the tiles it may the tiles, it may unnecessarily draw power from the tiles or may disrupt energy transmission if the tiles are in the path between a source and the destination tile. In embodiments the repeater tiles may be selectively tuned to bypass lossy objects that may be on the tiles. Routing protocols may be used to tune the repeater resonators such that power is routed around lossy objects.

In embodiments the tiles may include sensors. The tiles may include sensors that may be power wirelessly from the magnetic energy captured by the resonator built into the tile to detect objects, energy capture devices, people 1134, and the like on the tiles. The tiles may include capacitive, inductive, temperature, strain, weight sensors, and the like. The information from the sensors may be used to calculate or determine the best or satisfactory magnetic field distribution to deliver power to devices and maybe used to detune appropriate resonators. In embodiments the tiles may comprise sensors to detect metal objects. In embodiments the presence of a lossy object may be detected by monitoring the parameters of the resonator. Lossy objects may affect the parameters of the resonator such as resonant frequency, inductance, and the like and may be used to detect the metal object.

In embodiments the wireless powered flooring system may have more than one source and source resonators that are part of the tiles, that are located on the wall or in furniture that couple to the resonators in the flooring. In embodiments with multiple sources and source resonators the location of the sources may be used to adjust or change the power distribution within in the flooring. For example, one side of a room may have devices which require more power and may require more sources closer to the devices. In embodiments the power distribution in the floor comprising multiple tiles may be adjusted by adjusting the output power (the magnitude of the magnetic field) of each source, the phase of each source (the relative phase of the oscillating magnetic field) of each source, and the like.

In embodiments the resonator tiles may be configured to transfer energy from more than one source via the repeater resonators to a device. Resonators may be tuned or detuned to route the energy from more than one source resonator to more than one device or tile.

In embodiments with multiple sources it may be desirable to ensure that the different sources and maybe different amplifiers driving the different sources are synchronized in frequency and/or phase. Sources that are operating at slightly different frequencies and/or phase may generate magnetic fields with dynamically changing amplitudes and spatial distributions (due to beating effects between the oscillating sources). In embodiments, Multiple source resonators may be synchronized with a wired or wireless synchronization signal that may be generated by a source or external control unit. In some embodiments one source resonator may be designed as a master source resonator that dictates the frequency and phase to other resonators. A master resonator may operate at its nominal frequency while other source resonators detect the frequency and phase of the magnetic fields generated by the master source and synchronize their signals with that of the master.

In embodiments the wireless power from the floor tiles may be transferred to table surfaces, shelves, furniture and the like by integrating additional repeater resonators into the furniture and tables that may extend the range of the wireless energy transfer in the vertical direction from the floor. For example, in some embodiments of a wireless power enabled floor, the power delivered by the tiles may not be enough to directly charge a phone or an electronic device that may be placed on top of a table surface that may be two or three feet above the wireless power enabled tiles. The coupling between the small resonator of the electronic device on the surface of the table and the resonator of the tile may be improved by placing a large repeater resonator near the surface of the table such as on the underside of the table. The relatively large repeater resonator of the table may have good coupling with the resonator of the tiles and, due to close proximity, good coupling between the resonator of the electronic device on the surface of the table resulting in improved coupling and improved wireless power transfer between the resonator of the tile and the resonator of the device on the table.

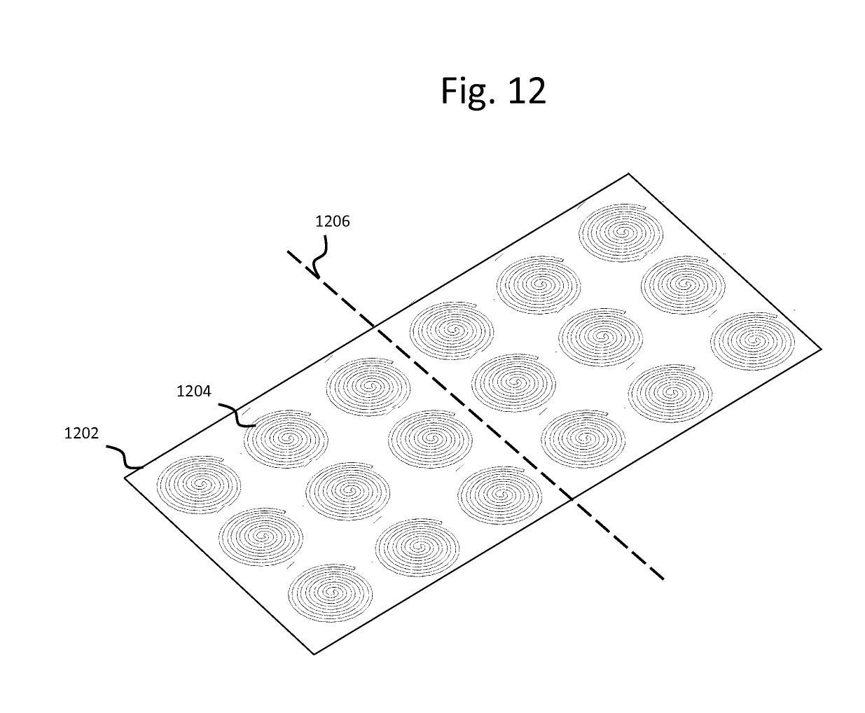

As those skilled in the art will recognize the features and capabilities of the different embodiments described may be rearranged or combined into other configurations. A system may include any number of resonator types, source, devices, and may be deployed on floors, ceilings, walls, desks, and the like. The system described in terms of floor tiles may be deployed onto, for example, a wall and distribute wireless power on a wall or ceiling into which enabled devices may be attached or positioned to receive power and enable various applications and configurations. The system techniques may be applied to multiple resonators distributed across table tops, surfaces, shelves, bodies, vehicles, machines, clothing, furniture, and the like. Although the example embodiments described tiles or separate repeater resonators that may be arranged into different configurations based on the teachings of this disclosure it should be clear to those skilled in the art that multiple repeater or source resonator may not be attached or positioned on separate physical tiles or sheets. Multiple repeater resonators, sources, devices, and their associated power and control circuitry may be attached, printed, etched, to one tile, sheet, substrate, and the like. For example, as depicted in FIG. 12, an array of repeater resonators 1204 may be printed, attached, or embedded onto one single sheet 1202. The single sheet 1202 may be deployed similarly as the tiles described above. The sheet of resonators may be placed near, on, or below a source resonator to distribute the wireless energy through the sheet or parts of the sheet. The sheet of resonators may be used as a configurable sized repeater resonator in that the sheet may be cut or trimmed between the different resonators such as for example along line 1206 shown in FIG. 12.

In embodiments a sheet of repeater resonators may be used in a desktop environment. Sheet of repeater resonators may be cut to size to fit the top of a desk or part of the desk, to fit inside drawers, and the like. A source resonator may be positioned next to or on top of the sheet of repeater resonators and devices such as computers, computer peripherals, portable electronics, phones, and the like may be charged or powered via the repeaters.

In embodiments resonators embedded in floor tiles or carpets can be used to capture energy for radiant floor heating. The resonators of each tile may be directly connected to a highly resistive heating element via unrectified AC, and with a local thermal sensor to maintain certain floor temperature. Each tile may be able to dissipate a few watts of power in the thermal element to heat a room or to maintain the tiles at a specific temperature.

Wireless Energy Transfer in Promotional Products

In embodiments wireless energy transfer may be adapted for promotional products such as drink coasters, drink glasses and cups, device chargers, phone accessories, key chains, ear-rings, toys, Frisbees or flying saucers, hats, and the like. Wireless energy may be used to illuminate the product, illuminate a logo on a product, and/or provide electrical energy to power a product and/or charge a battery and/or power or initiate communication capabilities of the product or a device in the vicinity of the product.

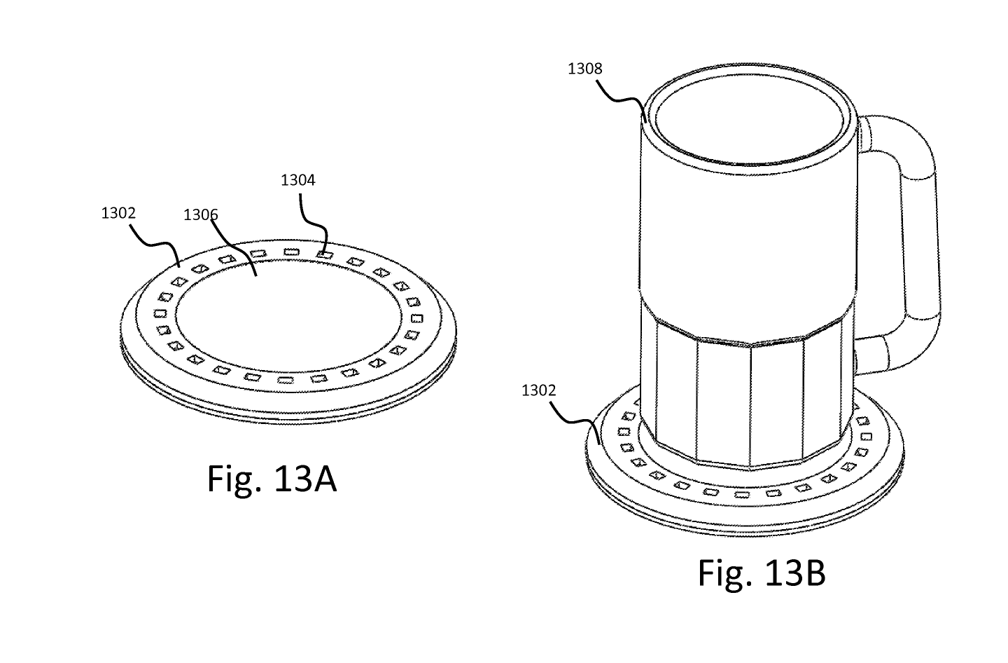

For example, wireless energy resonators may be integrated into a drink coaster. As depicted in FIG. 13A, a drink coaster 1302 integrated with an energy capture resonator (not shown) may be used to capture energy from a source resonator that may be integrated into furniture, walls, displays, lamps, carpets, chairs, seats, tables, bars, counters, stools, couches, and the like, an/or placed next to the coaster, under the coaster, under the table, over the table, and the like. In embodiments the energy captured by the resonator in the drink coaster may be used to power one or more lights 1304 or an area of the drink coaster which may be used to illuminate a logo 1306. In embodiments the lights of the coaster may be used to illuminate a drinking glass 1308 placed on top of the coaster 1302 as depicted in FIG. 13B. In embodiments the lights may change brightness and/or color for artistic effect, or to provide entertainment, or to provide for communications, and the like.

In embodiments the coaster may have a weight sensor, such as a strain sensor, that is powered by the energy captured by the resonator and that detects when an empty drink is placed upon the coaster and enables lighting of the wirelessly powered lights on the coaster to alert a bartender or server. The pressure sensor may be calibrated to only turn on for a specific weight range such that the lights do not turn on or off when the drink is not on the coaster, for example. In embodiments the drink coaster may have a temperature sensor to detect the temperature of a hot drink such as coffee or tea. When the temperature drops below a specific value the light may turn on or off or flicker or send a signal such as a wireless communication signal to a waitress, a kitchen, a serving station, a hostess station and the like, to refresh the coffee or drink. In embodiments, the coaster may comprise a heater such as a resistive heater or a Peltier heater, or a cooler such as a Peltier cooler or other type of thermoelectric cooler, and may be used to keep drink containers placed on the cooler hot or cold, respectively.

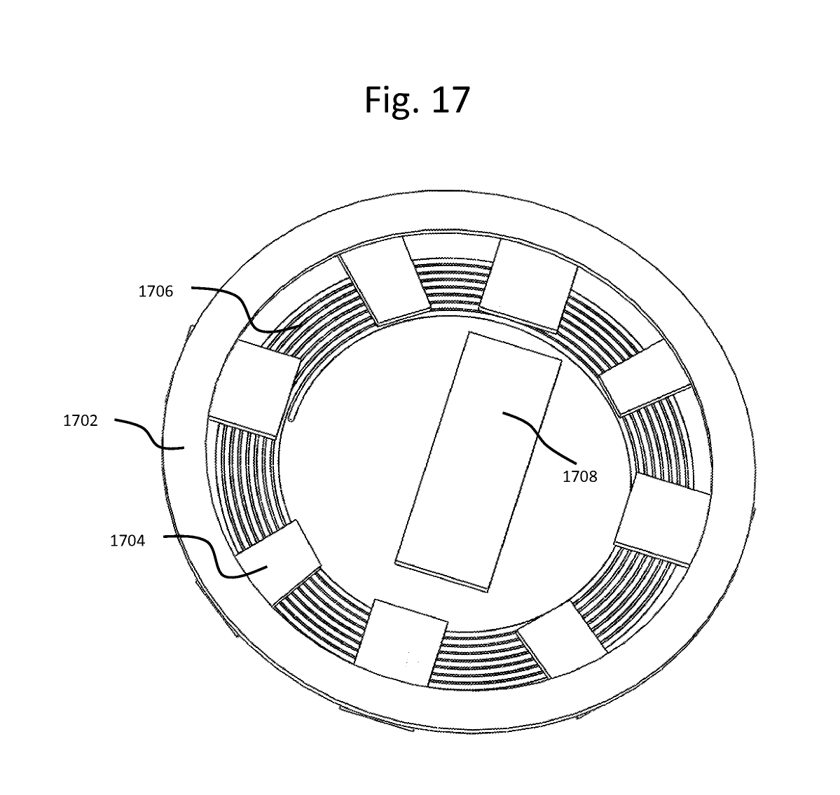

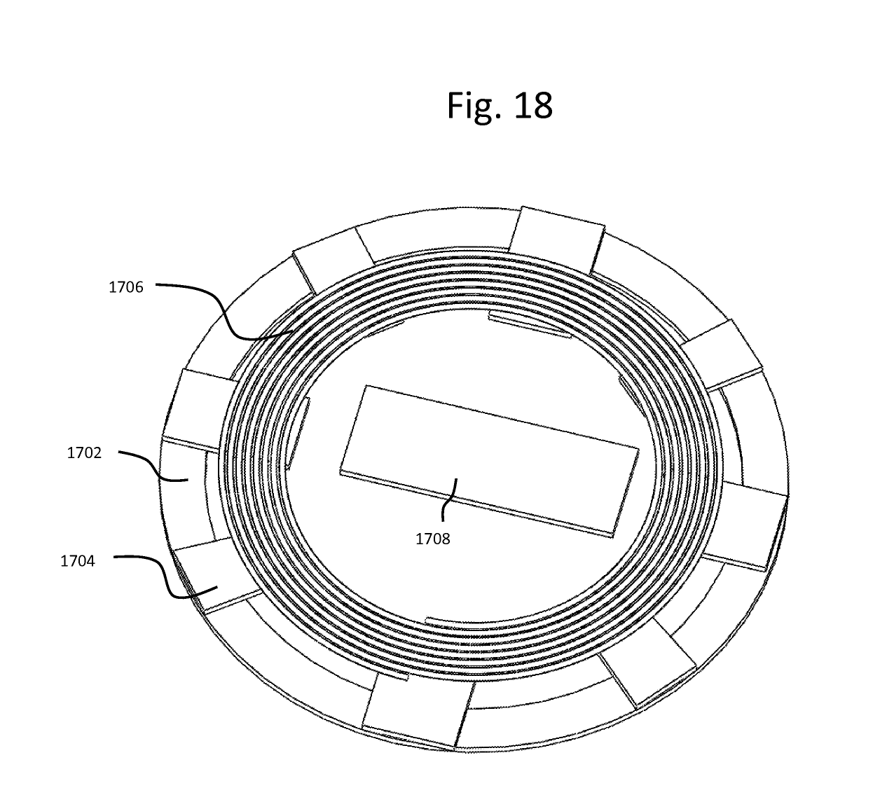

Wireless energy capture resonators configured for integration into drink coasters may be designed to allow metal objects such as aluminum cans to be placed on top of the coaster without significantly affecting the power transfer to the coaster. An example is shown in FIGS. 17 and 18. In an exemplary embodiment, a resonator 1706 comprising a wire, printed circuit board, litz wire, a resonator coil, or the like, may be wound in a flat spiral. An LED ring 1702 or other light emitting devices or other sensors may be positioned on top of the resonator coil in an assembly. In embodiments the LED ring 1702 or other sensors may comprise lossy materials and may perturb or affect the electrical parameters of the resonator coil 1706, such as its inductance, resistance, quality factor, and the like, and the wireless energy transfer performance. In embodiments the assembly may include blocks, strips, chunks, and the like of magnetic material 1704 between the lossy materials and the resonator coil. The magnetic material 1704 may also be positioned to shield the resonator coil 1706 from any lossy objects such as aluminum cans that may be positioned on top of the drink coaster. The magnetic material may comprise multiple tiles of magnetic material assembled to completely cover an area, or to partially cover an area. In embodiments, magnetic materials assembled to partially cover an area may weigh less and be smaller than magnetic materials assembled to completely cover an area and may still yield acceptable performance. In embodiments, magnetic material tiles may be arranged in a manner to spokes on a wheel to partially cover a circular area, as shown in FIGS. 17 and 18.

In embodiments, magnetic material may be ground up and mixed with gels, glues, pastes, paints and the like, and may be applied to the resonator coil to change its inductance and/or to shield the resonator.

The assembly may also include circuit boards 1708 that may include any capacitors that may be used to provide impedance matching and/or resonant frequency control of the resonator or that control other operations of the resonator. The circuit board may include any other electronics needed to rectify or manipulate the energy captured by the resonator. By way of example, but not limitation, the circuit board may comprise processors, switches, transistors, diodes, sensors, one or more wireless communication antennae, chips for implementing wireless communication protocols, power converters and conditioners, clamping circuits, control circuitry, and the like.

In embodiments the lights of the drink coaster may be powered directly from the oscillating currents of the resonator coil without rectification. In embodiments LEDs may be powered with the use of a current limiting resistor to prevent reverse breakdown of the LEDs. In embodiments, rectification of the captured energy signals may be provided by a combination of standard electrical diodes and light emitting diodes.

Wireless power may be transferred between resonators that are completely enclosed in sealed housings comprised of substantially non-lossy materials, including the present embodiment of a housing shaped as a drink coaster. In embodiments, source resonators may also be enclosed in housings and/or may be positioned in places that do not get wet or are not subjected to large excursions of temperature, humidity, cleanliness, and the like. Given that the electronics required for power transfer may be completely enclosed in a housing, wireless power transfer may be safe and efficient even in the presence of liquids, high humidity environments, over large temperature excursions and the like. In embodiments, power transfer may be achieved when drinks, liquids, food, dust, and the like, are spilled on the coasters or source resonators. In embodiments, wireless resonators that are in sealed enclosures may be cleaned using normal cleaning methods, including methods that completely submerge the resonator housings in water, such as in a dishwasher cleaning cycle and/or immersion in chemical cleaners. In embodiments, wireless power transfer can be achieved when any or all of the resonators in watertight enclosures are immersed in liquids.

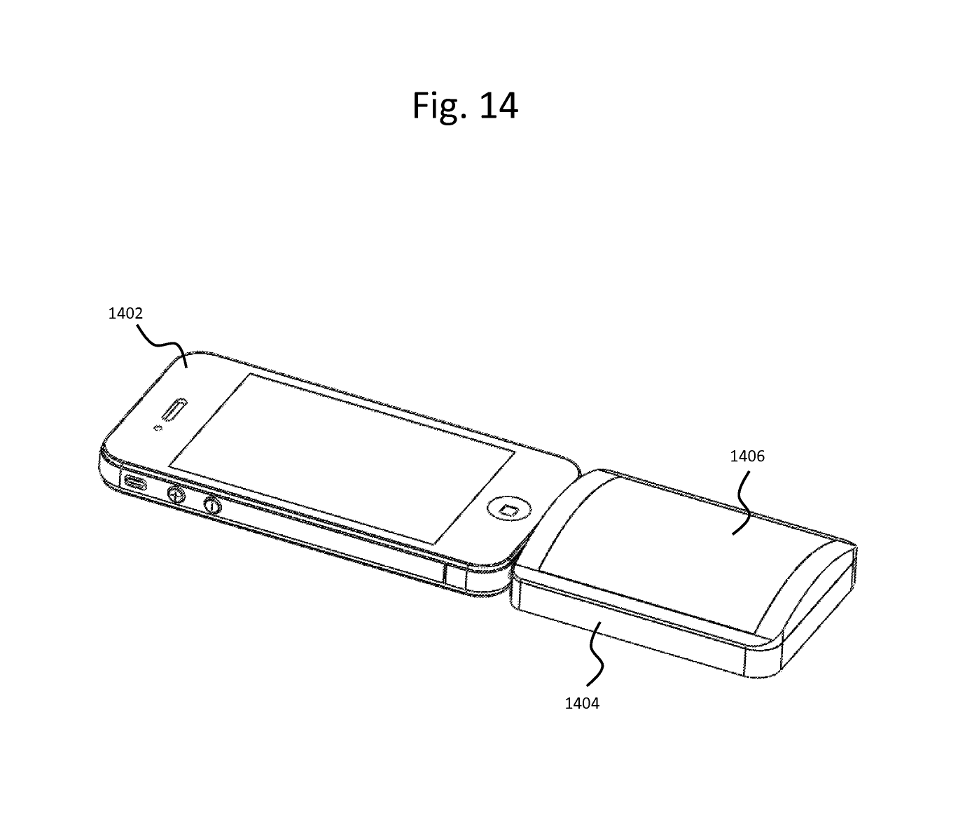

Another example of a wirelessly enabled promotional product is depicted in FIG. 14. A dongle 1404 for a mobile device 1402 may be fitted with a wireless energy capture resonator and electronics to capture energy from a source in a table, bar, counter, and the like or on a table, bar, counter, and the like and illuminate an area 1406 on the dongle 1404 which may contain logos or depicts other promotional information. In embodiments, wireless energy may be simultaneously supplied to the mobile device to power and/or charge the mobile device. In embodiments, a user may have to press a button or touch an icon on a screen to initial power transfer to the mobile device, or to pay for power transfer to the mobile device and the like. In embodiments, a program on the mobile device may be used to initiate power transfer to the mobile device. In embodiments, certain settable parameters such as cost of energy, source of energy, length of energy exchange, amount of energy exchange charges and the like may be programmed in the mobile device or entered by the user to control the wireless power transfer.

In embodiments the lights of the dongle may change color, intensity, blink rate, and the like to indicate different transferred power levels or indicate the amount of energy transferred to the attached phone or electronic device. In embodiments, the dongle may include authentication and/or identification components so that the screen of the mobile device may display the logo of the company that supplies the dongle when that mobile device is being charged or powered by that dongle. In embodiments, messages from the sponsoring company or companies may be displayed on the mobile device screen, describing promotions, local promotions, discounts, announcing new products and/or services and the like.

In embodiments, a dongle 1404, for a mobile device may be fitted with electronic circuit components to allow the mobile device to serve as a wireless power source and/or repeater. In embodiments, the device that serves as the wireless power source may receive payment, credit, points, and the like, from a sponsor such as the establishment owner, or the company that supplied the dongle, in exchange for supplying power to the promotional area. In embodiments the mobile device may be capable of bi-directional energy flow using one magnetic resonator or multiple magnetic resonators. In embodiments, programs running on the mobile device and/or dongle, and/or use interfaces may be used to control the bi-directional flow of wireless energy to and from the wireless power resonator or resonators of the mobile device. For example, a user may want to sell energy stored on her mobile device to a nearby mobile device. Then, her phone may be set up to communicate with near-by devices to set up a wireless power exchange. In embodiments, the communication may exchange information such as the power requirements of the near-by device and the price that device is willing to pay for energy. In other embodiments, the energy may be exchanged for free and in some embodiments energy exchange may take place without the need for wireless communications. In other embodiments, a mobile device may offer to supply wireless energy to other devices only during certain times of the day, or when it is plugged in, or when it is receiving wireless energy from another source, or when its battery charge state is above a certain level and the like. In still other environments, the mobile device may be configured not to provide energy to other devices, or to only provide energy in case of emergency, or in certain environmental conditions and the like.

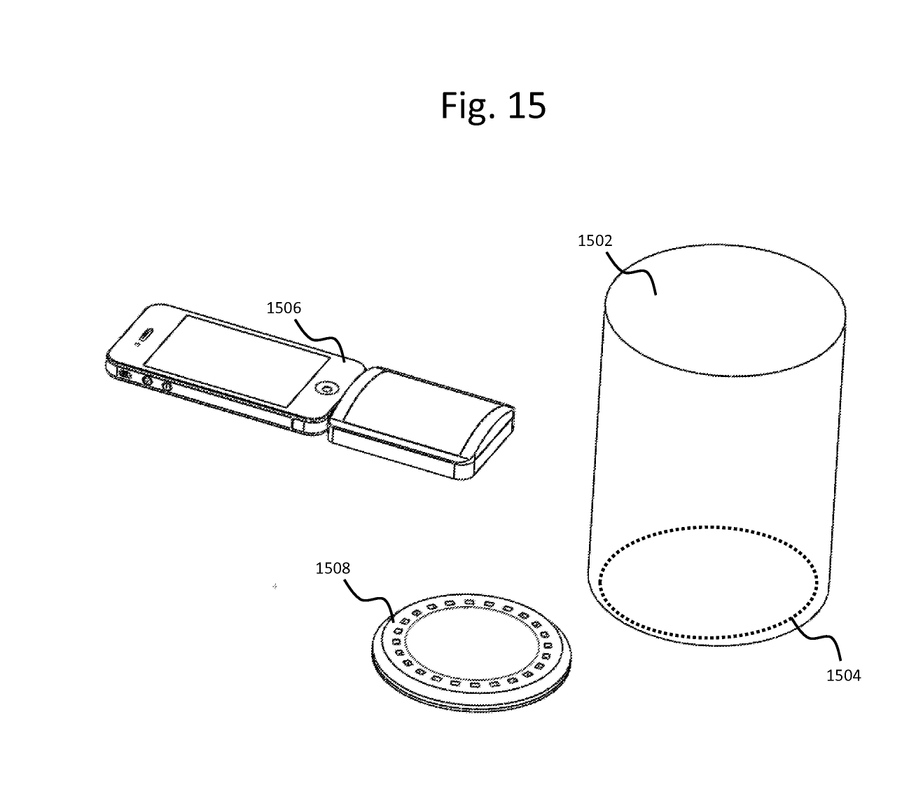

In embodiments the promotional items 1506, 1508 may receive power when placed next to a source 1502 as depicted in FIG. 15. The item may be powered and/or may be charged when placed on a flat surface around a source 1502 with a source resonator 1504 which may be a capacitively loaded conductor loop comprising litz wire, a printed circuit board coil, or solid core wire and the like. Energy capture or device resonators integrated into a drink coaster 1508 or a dongle 1506 may be placed around the source 1502 and receive power.

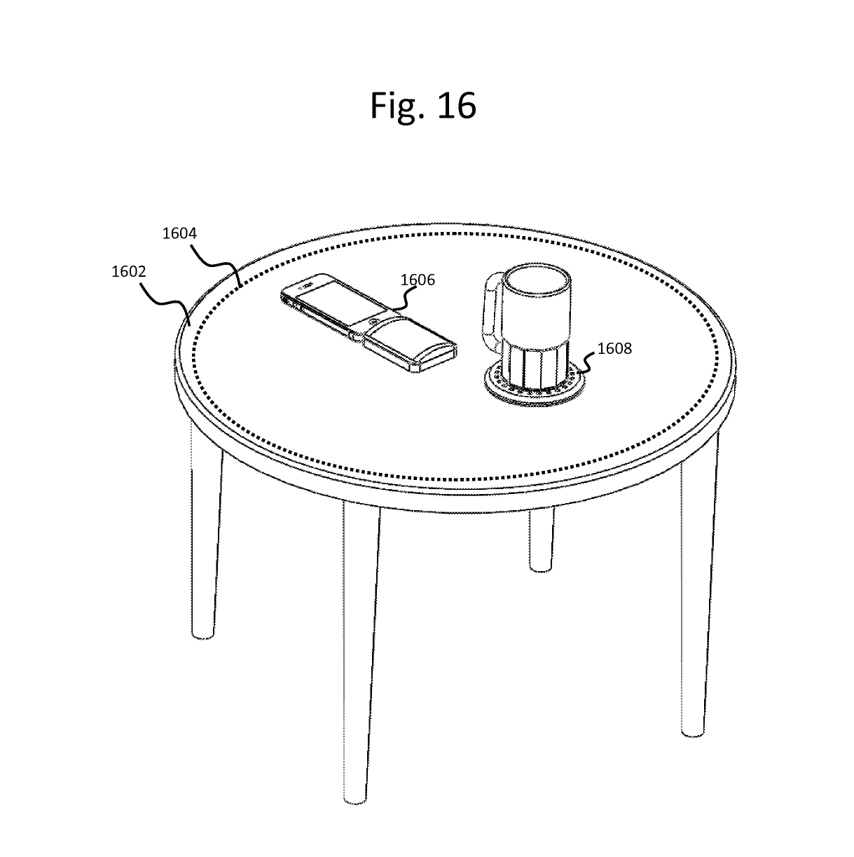

In another embodiment the promotional items 1606, 1608 may receive power when placed on furniture 1602 integrated with a source resonator 1604 as depicted in FIG. 16. A source resonator 1604 comprising litz wire, a printed circuit board, and a like may be integrated to the table, bar, counter and the like or attached to the bottom or top of the table, bar, counter, and the like, surface energizing the area on top of the table, bar, counter, and the like, onto or nearby which devices with wireless capture resonators may be placed.

In embodiments the wireless energy source resonators may further comprise magnetic material under or around the resonator coil similarly to the magnetic material 1704 placed around the resonator coils 1706 in the device resonators depicted in FIG. 17. In embodiments the device resonators with the magnetic materials may couple to and transfer energy with source resonators that do not have magnetic material. In other embodiments the device resonators may couple and transfer energy with source resonators comprising magnetic material.

In embodiments, source resonators may comprise facilities to illuminate a product, illuminate a logo, illuminate a logo on a product, or provide electrical energy to power a product and/or power or initiate communication capabilities of the product or a device in the vicinity of the product. In embodiments, source resonators may be packaged and may include physical markings such as logos and/or color schemes. In embodiments, source resonators may be configured to play jingles, theme songs, catch phrases, audio clips and the like. Source resonators may be sponsored by companies and may display sayings such as “power brought to you wirelessly complements of ACME” or any such marketing slogan.

Source resonators may be wired to the electric grid or to any type of power panel. Source resonators may be powered by one or more battery packs, one or more solar cells, or any other type of energy source discussed throughout this disclosure. Battery power packs may be marked to include targeted marketing messages, sponsorship messages, advertisements, commercials, and the like. Source resonators may be powered by other devices such as cell phones. In an embodiment, one person may use the battery pack in their cell phone to power a wireless source resonator on or in a piece of furniture and share their power with other wirelessly powered devices around the table. The cell phone battery pack may be wired to the source resonator and/or the cell phone battery pack may supply power wirelessly to the source resonator and/or a repeater resonator, and/or a device resonator.

In embodiments, repeater resonators may be embedded in furniture and may receive power from a wired source or a battery powered source. In embodiments, the repeater resonators may also be marked with logos or other types of branding. Repeater resonators may comprise lights, buzzers, speakers, displays and the like and may be used to extend or enhance wireless power transmission used in promotional applications. For example, the drink coaster described above may be a repeater resonator in addition to a receive resonator for powering the LED lights.

In some embodiments, surfaces, shelves, furniture, and the like, that make up a promotional area, may comprise additional items such as displays, touch screen displays, game consoles, wireless internet devices, monitors, and the like that may be configured as wireless power sources, repeaters, devices, or such items may be battery powered or directly wired to the electrical mains. Such devices may couple to handheld devices such as cell phones, smartphones, iPads, iPods, game consoles, tablet computers, and the like, so that a group of people in the promotional area can view media generated by other people's devices while wireless power is exchanged amongst at least some of the wireless power source, repeater, and device resonators. For example, a group of friends may walk into a bar and sit down at a table that comprises any of a wireless power source and a wireless power repeater, and their wirelessly enabled devices in their hands, pockets, bags, backpacks, and the like, or placed on the table will be able to be charged or powered by the table. In a further example, the table may comprise a touch screen monitor that may wirelessly couple to at least one of the users handheld devices. That user may enable their device to send any type of data such as photos, text messages, twitter messages, music videos, internet content, and the like, to the monitor so that everyone at the table may view it. Data such as that associated with interactive exchanges may also be displayed so that people may use the touch screen to play games, or draw pictures, or communicate with other people via a wireless information link.

In embodiments, the monitor screen may include promotional messages which may be displayed as a ticker or as crawl messages, as pop-up messages, as pull down messages, as advertisements, and the like. The monitor screen may comprise wireless power source resonators, repeater resonators and/or device resonators. The monitor screen may be used to communicate with the bar tenders, the servers, and/or anyone associated with the establishment in which the table is placed. Cameras on the monitor may be used to video chat with people in other portions of the establishment or with people at other establishments. The monitors may be used to display photos or videos of activities happening within the establishment, such as close-up shots of performers on a stage that are a distance away from the table, for example.

In embodiments the energy capture resonators may be adapted to power displays, smart cards, sound cards, wireless hubs, and the like. In embodiments a mobile credit card or mobile smart card reader may be integrated with the capture resonator depicted in FIGS. 17 and 18 and receive energy from an energy source integrated into the table or placed on the table. The card reader may turn on when a card is placed near the reader or on the reader allowing customers to pay bills at their tables without requiring power cords or batteries to the card readers.

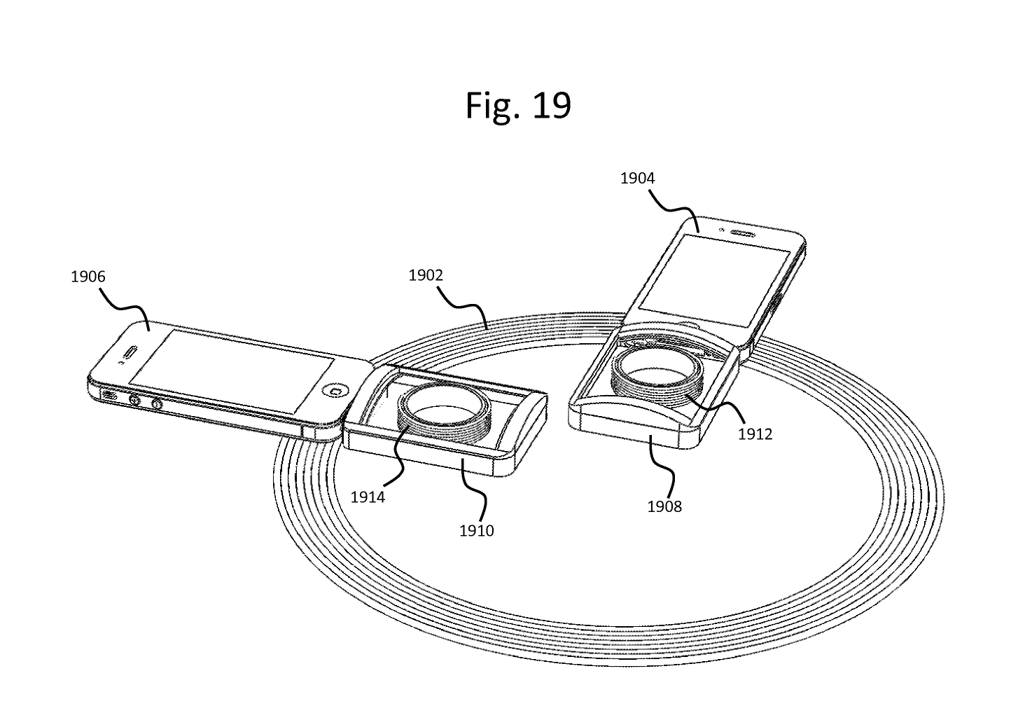

FIG. 19 shows one configuration that uses the resonator coil assembly as a dongle or attachment to a mobile phone that may be used charge to power the phone. In the example configuration the device resonator coil assembly 1914 is designed to fit a dongle attachment 1910 that may be connected to a mobile phone 1906. In the example configuration the device resonator coils may receive energy from source resonator coil 1902. Multiple mobile phones with an attached or coupled dongle comprising a device resonator may be positioned near the source resonator to receive energy from the source. Mobile phones and other electronic devices may be positioned in the charging area that is the circumference of the source resonator to receive power.

In embodiments, the dongle may be sized and shaped to have additional functions. For example the dongle may be part of a key chain, a bottle opener, a memory stick, an audio speaker, a microphone and the like. In embodiments, an electrical connector may be used to supply power from the dongle to the mobile device. In other embodiments, the wireless power receiver resonator may be built into the mobile device such as being part of the mobile device sleeve, cover, enclosure, battery pack, circuit board and the like. In embodiments, the mobile device may comprise a secondary inductive coil of a traditional inductive energy transfer system and a dongle may supply power wirelessly to the mobile device. In embodiments, a primary coil of a traditional inductive wireless power system and/or a secondary of a traditional inductive wireless power system may tightly couple to a high-Q resonator to exchange power wirelessly over a greater distance and/or at higher efficiency.

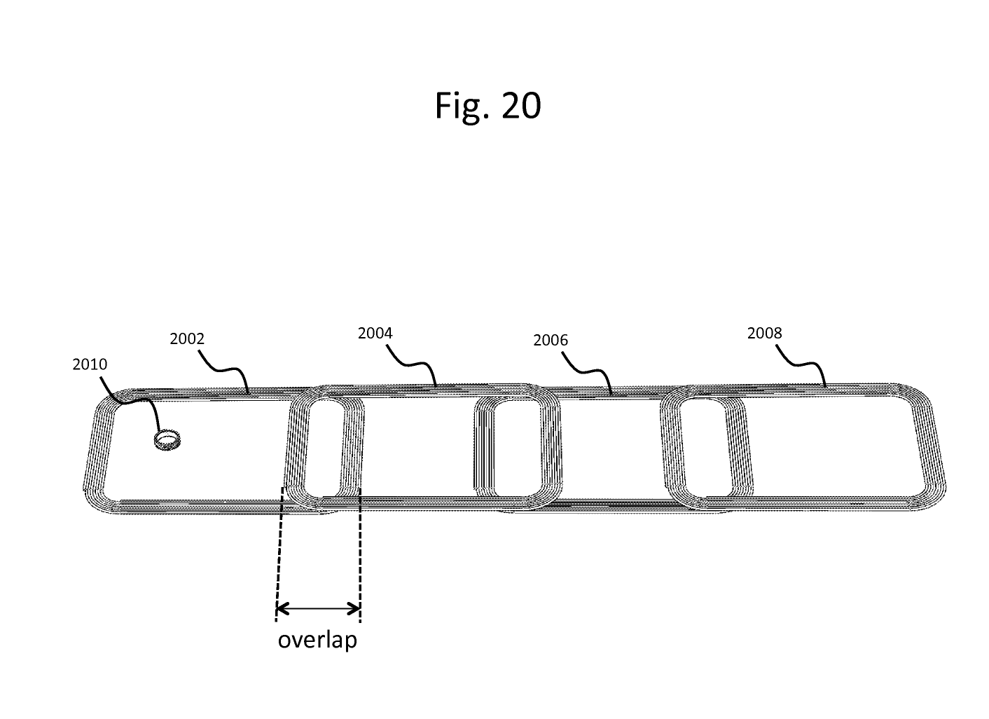

In embodiments the charging area or the effective area of a high-Q source where devices may be positioned on, near, over, and the like may also be extended or increased with the use of repeater resonators. In embodiments one or more repeater resonators comprising a resonator coil, capacitors, and optionally additional power and control circuitry may be placed near a source resonator coil that is coupled to a power source to extend or shape the effective charging area. For example, to create a long charging area that may cover or be shaped to cover a rectangular table, bar, counter, and the like, multiple repeater resonators may be positioned near a source resonator. FIG. 20 shows an example configuration that uses repeater resonator to extend the charging or the effective area of a source. In the example embodiment shown in FIG. 20 the effective charging area of single source resonator coil 2002 may be extended by positioning repeater resonator coils 2004, 2006, 2008 near the source resonator coil 2002. In this configuration only the source resonator coil 2002 is coupled to a power source (not shown). Energy from the source resonator coil 2002 may be transferred to the adjacent repeater resonator 2004 and then from the adjacent to the next 2006 and so on. Using the repeater resonator coil, the effective charging area of the source may be increased to several times the size of the source using the repeaters. In embodiments the repeater resonators may be positioned or shaped to provide different effective areas. In embodiments the system may comprise more than one source resonator coil coupled to a power source with multiple repeater resonators that are used to extend the effective area of the source.

In embodiments using repeater resonators to extend the effective area of the source it may be beneficial to overlap the adjacent resonator coils to reduce or eliminate possible dead spots or areas with low efficiency or low coupling. FIG. 20 shows a system of resonators with an overlap of adjacent resonator coils. In a system where adjacent resonator coils or a source or a repeater are not overlapped but abutted or separated by a distance a device resonator 2010 may have dead spots of areas of low coupling and low efficiency in the areas where the two or more resonator coils meet thereby making the effective area created by repeater resonator coil non continuous. Overlapping adjacent resonator coils may provide a continuous effective area without interruptions. A device resonator coil that is moved or positioned above a source comprising the source and one or more repeater resonators may always be coupled to at least one source or repeater as it is moved across the effective area. In embodiments the overlap between the adjacent resonator coils may be adjusted based on the size of the device resonator coil size, the size of the source resonator, the size of the repeater resonator, the position relative to the source resonator, and the like. In embodiments the overlap between the adjacent resonators may be equivalent to 5% or 10% of the longest dimension of the resonator coil. In embodiments the overlap between adjacent resonators or resonator coils in a system may be non-uniform. Resonator coils that are closer to the source may have a different amount of overlap than the resonator coils that are further away from the source resonator coil. In embodiments, resonators coils may have a larger overlap the further away they are from the source resonator coil. For example, for the system shown in FIG. 20 the overlap between the source resonator coil 2002 and the first repeater resonator coil 2004 may be different than the overlap between the last two repeater resonator coils 2006, 2008.

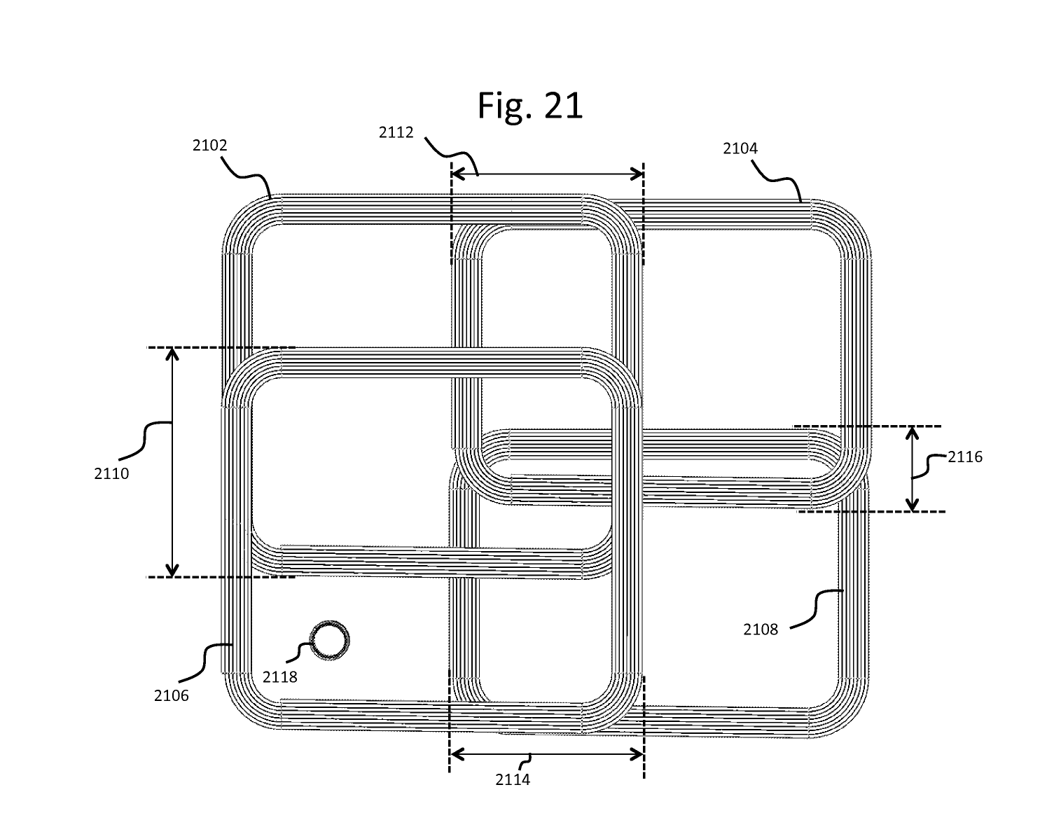

In embodiments the repeater resonators may be used to extend the effective size of a source in more than one dimension as shown in FIG. 21. Repeater resonator coils 2102, 2104, 2108 may positioned in a 2 dimensional array around a source resonator coil 2106 increasing the effective area of the source resonator coil in two dimensions. The resonator coils may be sized and positioned to overlap adjacent resonator coils to reduce or eliminate the dead spots or areas of low efficiency in areas between adjacent resonator coils.

In embodiments the amount of overlap between adjacent resonator coils may be adjusted or sized based upon the relative phase of the current induced in the resonator coil. In embodiments, repeater resonator coils with circulating currents that are approximately π/2 of out phase from one another may have less overlap than resonator coils that are in phase or in proximity to the source resonator coil. FIG. 21 depicts a configuration with one source resonator coil 2106 coupled to a power source whose effective areas is increased with the three repeater resonator coils 2102, 2104, 2108. The amount of overlap between the adjacent resonator coils may be different and may be based on their position relative to the source resonator coil and relative phase of adjacent resonator coils. For example, in this configuration, the resonator coils 2102, 2108 that are directly adjacent to the source resonator coil 2106 may have a relatively large overlap 2110, 2114 with the source resonator coil to improve the coupling between the adjacent coils and reduce or eliminate dead spots or areas of low efficiency that may occur in the transition zone between two resonator coils. The overlap between adjacent resonator coils may be reduced for repeater resonators that are adjacent but that carry currents that are approximately π/2 out of phase from one another as would be the case of resonator coils 2104 and 2108 where the overlap 2116 is relatively small compared to the other overlaps in the example system. In this case the overlap 2116 may be sized to reduce the dead spots between the resonator coils. This relative sizing of resonator overlaps may be continued as the resonator array gets larger and/or uses more repeater resonators.

In embodiments, the combination of one or more source resonators and one or more device resonators may be advantageous to assembly charging areas, zones, regions, and the like that are customizable from a relatively small number of stock parts. For example, a long and thin charging area such as might be appropriate for a countertop and/or a bar, may be assembled by using one or more source resonators and one or more repeaters resonators laid out in a linear array such as is shown in FIG. 21. A different arrangement of source and resonators and repeaters may be assembled to provide a substantially square charging area as shown in FIG. 21 and as might be appropriate for a café table, a coffee table, a kitchen tale, a desk and the like. Being able to assemble and customize the shape and size of the charging area from a relatively small set of building blocks may be advantageous for installing wireless power sources in a wide variety of establishments. Also, the speed of installation may be greatly improved as the sources with specific charging areas, zones, regions, and the like can be customized on the spot, at the installation point. Thus there are many advantages to creating charging areas, zones, regions and the like from combinations of wireless power source resonators and wireless power repeater resonators.

Desk Charger

In many environments a convenient and useful arrangement for the energy source is a pad configuration where the source is orientated and positioned to allow devices to be placed on top of the source to receive energy. For large devices or multiple devices, this arrangement may require a pad to be relatively large to accommodate all the devices being placed on the pad. A large pad may be obtrusive for some users as it may take up lots of room on a desk, spoil the appearance of a desk or work area, and the like.

A large charging area on a surface, such as a table, large enough to accommodate a plurality of devices without requiring a large pad on top of the user's desk or other surface may be provided with a system comprising one or more repeater resonators. The system may include a hidden repeater that may be placed below a structure, table surface, placed in a drawer, hidden inside a desk or table or counter or other surface, and the like.

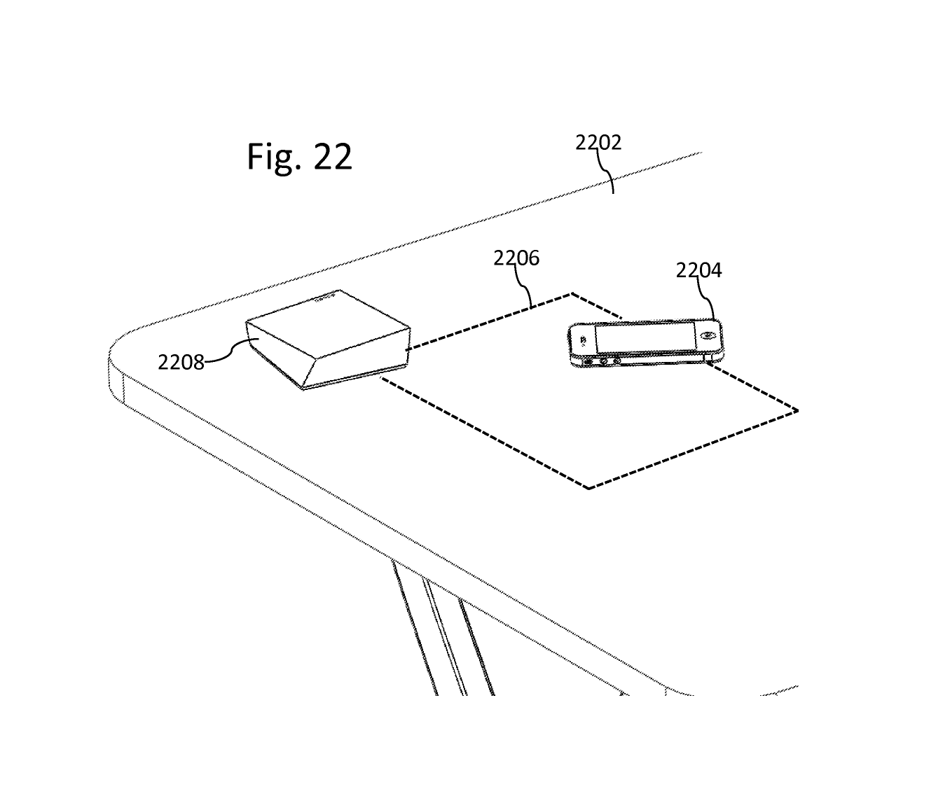

One exemplary embodiment of the system with a repeater resonator is shown in FIG. 22. The system comprises a source 2208 that is coupled to an energy source like a battery or a power outlet (not shown). The source comprises amplifier electronics and a source resonator that may be configured to generate oscillating magnetic fields. The source 2208 may have a small footprint, so as to take up a small area of the work surface 2202. The footprint of the source may be the area of the source enclosure that is substantially in contact with the work surface. The footprint of the source may be the area of the work surface that is taken up by the source. In embodiments, the source may be capable of charging or powering a wireless device within an energized volume of the source. The energized source volume may be characterized as having dimensions in an orthogonal coordinate systems such as in a Cartesian coordinate system of “x”, “y”, and “z”. In embodiments, the “x-y” plane may be parallel to the work surface. In embodiments, the footprint of the source may be determined by multiplying the “x” and “y” dimensions of the source enclosure. In embodiments, the “x-y” dimensions of the source energized volume may be larger than the source footprint. In embodiments, it may be desirable to have a system energized volume that is larger than the source energized volume. In embodiments, this larger system energized volume may be achieved using repeater resonators.

The exemplary system shown in FIG. 22 includes one repeater resonator 2206 positioned near the source 2208, but may include additional repeater resonators that may be configured in a variety of arrangements, all near the source, arranged in a line, daisy-chained, arranged in a symmetric pattern, arranged in an asymmetric pattern, and the like. The repeater resonators may be passive resonators and may not be physically connected to an energy source. The repeater resonators may couple to the source resonator of the source 2208. The repeater resonator may be attached to the bottom of the work surface or desk and may create a charging area on top of the work surface without a physical pad on top of the work area. The “x-y” dimensions of this system energized volume may be the area that is above the repeater resonator and may be large enough to provide power to many devices and/or devices of various sizes without requiring the placement of a physical pad that may take up a large surface area of the desk. In this exemplary embodiment, only the small powered source 2208 may be positioned in a corner of a desk and on the top of the work surface. A device such as a cell phone 2204 with a device resonator configured to couple to the magnetic fields of the repeater may be placed on the area above the repeater resonator and receive energy from the source via the repeater. Note that in this exemplary embodiment, the source 2208 could have been placed below the work surface or could have been in the work surface.

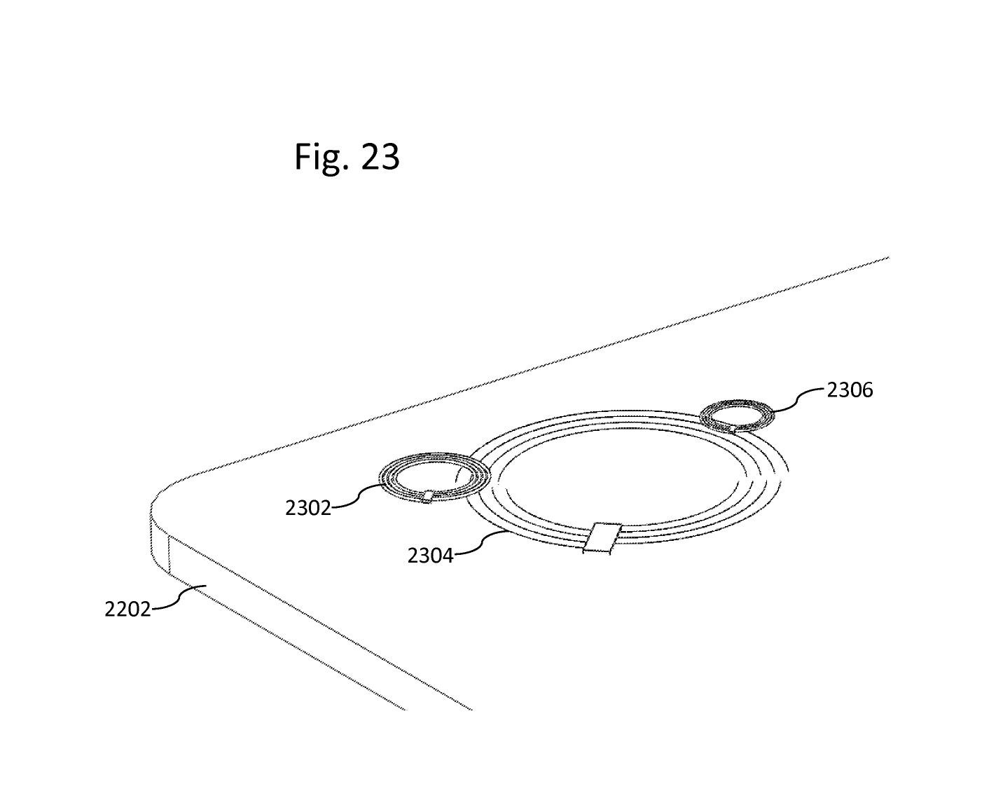

In embodiments the source, repeater, and device resonators may be implemented using a variety of resonator shapes, sizes, and types. The resonators may comprise air core loops of a conductor. For example FIG. 23 shows a possible resonator configuration of the system. A source resonator coil 2302 placed on top of the desk may couple to the repeater resonator coil 2304 positioned under the desk surface and may transfer energy to a device resonator 2306 positioned on top of the desk surface. In other embodiments the resonators may be the so called planar resonators comprising conductors wrapped around blocks of magnetic material. The system may generally use any type, size, shape, and the like, of resonators and may include resonators comprising printed circuit boards, Litz wire, solid core wire, and the like.

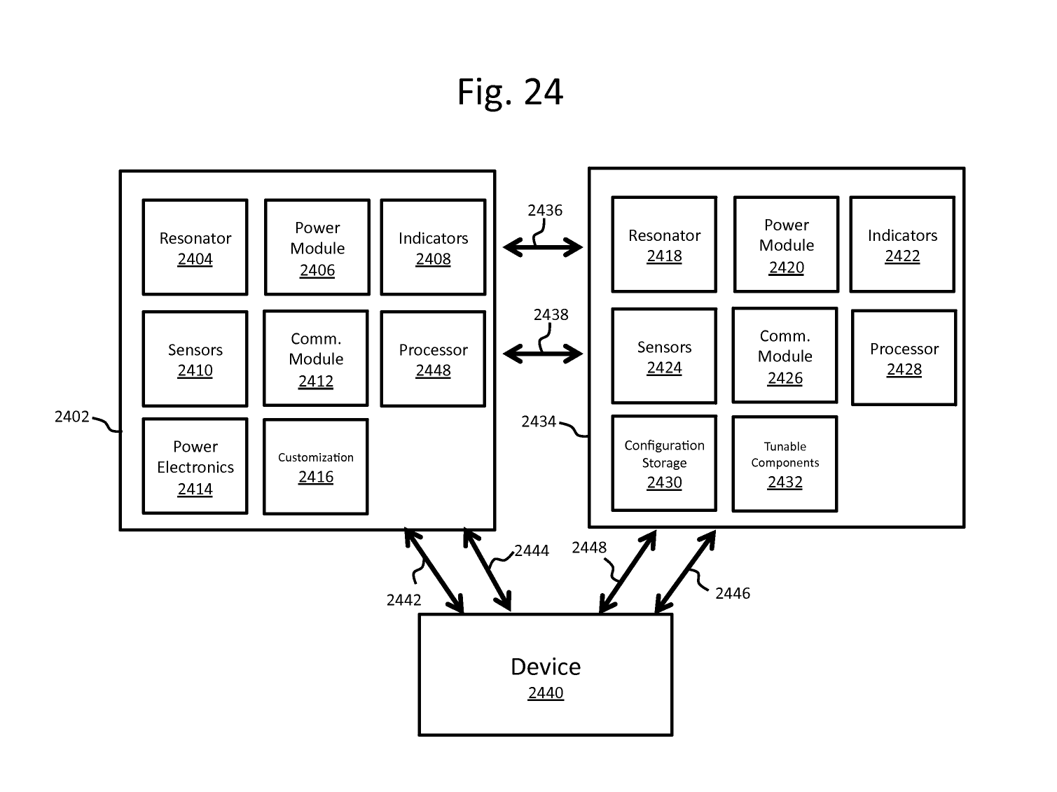

FIG. 24 shows a block diagram of the components and modules that may be used in a system comprising a source device 2402, a repeater device 2434 and a receiving device 2440. The source device may include one or more resonators 2404. The resonators 2404 may be any one of the resonators described herein or known in the art. The type of resonator used may depend on the exact configuration of the system, the desired system parameters, and the like. For the system shown in FIG. 22, for example, capacitively loaded conducting loop resonators, oriented with their dipole moments perpendicular to the work surface area may be preferred in some applications. In embodiments with more than one resonator, the resonators may all be the same type, or they may be different types, shapes, sizes, positioned in different orientations, configurations, and/or the like. The resonator(s) 2404 may be electrically coupled to one or more power electronics components and/or modules 2414 that may energize the resonator(s) 2404. The power electronics module 2414 may include one or more power amplifiers, matching networks, voltage/current sensing elements, and/or the like and may be used to generate oscillating voltages/currents that are used to energize the one or more resonators 2404. The one or more resonators 2404 may generate an oscillating magnetic field once energized be the power electronics 2414. The characteristics of the magnetic field generated by the one or more resonators may be controlled by controlling elements of the one or more resonators 2404 and/or the power electronics components 2414. For example, the frequency of the magnetic field may be controlled by changing the frequency of the oscillating voltages/currents used to drive the resonators. Likewise, the strength or magnitude of the magnetic fields, their phase, relative phase, and the like may be controlled by changing the properties of the amplifiers, values of components such as capacitors and/or indictors of the power electronics module 2414. In embodiments the control of the magnetic fields may include a closed loop control method based on feedback from sensors 2410 which may include magnetic field sensors and/or electric field sensors.

The source device 2402 may include additional sensors 2410 such as temperature sensors, gravity sensors, compass sensors, motion sensors, accelerometers, and/or the like that may be used by the system to configure the operation of the source. An orientation sensor may be used to determine in which position the source device is oriented. Depending on which orientation the source device is positioned different source resonators may be activated or driven by the power electronics. The source device 2402 may be configured to have different functionality depending on its position and orientation. For example, the source device 2402 may be configured to activate different types of resonators depending on which side of the source device is positioned on top or parallel to the table work surface. The source device 2402 may be configured as a cube with one or more different types of resonators on each if its sides, for example. Depending on how the cube is positioned and oriented with respect to the work surface a different one or set of resonators may be activated, allowing the source device be compatible and configurable to one or more different applications and system configurations.

In some embodiments the source device 2402 may also include a communication module. The communication module may include necessary antennas, protocols, logic, and controllers for use of one or more out-of-band communication channels and technologies such as Wifi, Bluetooth, Zigbee, and the like. In some embodiments, the communication module may include, or include instead the necessary components, controllers, protocols, and the like for in-band communication with other source devices, repeater devices, and receiver devices. The in-band communication may utilize the resonators and/or the wireless energy transfer fields to send information.

The communication module may be used by the system to coordinate wireless energy transfer, to tune or establish operating parameters of the resonators and/or other components of the system. The communication module may be used to send and/or receive status information of the source device and other components of the system. Status information from the repeater device and/or the receiving device may be received by the communication module 2412 and used to configure the source. In some embodiments the source device 2402 may be configured, updated, and/or controlled with a remote device such as a computer, a tablet computer, a smart phone and/or any hand held device, using the communication module 2412.

In embodiments, the source device may include one or more indicators 2408 which may be used to generate one or more auditory, visual, tactile, and/or the like feedback to a user or operator regarding the status of the system, devices, components, field strength, and/or the like. Indicators may be lights, LEDs, graphic displays, audio speakers, vibrators, lasers, optical output devices, wireless signals, and the like. Indicators may show that the system is on, that a repeater device has been detected, the status of a repeater device, that a receiving device has been detected, and the like. The indicators may display the charging status or one or more receiving devices and the expected time to finish charging, for example. The indicators may be configurable and/or customizable. Indicators for coupling strength to a repeater device from the source device may be configured depending on the preferences of the user. Some users may prefer or require a high efficiency of power transfer and may desire at least at 30% efficiency of energy transfer. The indicator, such as an LED, showing coupling to the repeater device may be configured by the user to only light up when the coupling is strength is at least a specific strength. Other users who may tolerate lower power transfer efficiencies may configure the indicator to light up at a lower threshold, for example.

In some embodiments the source device 2402 may include customization module 2416. The customization module 2416 may include data storage to store user preferences, settings, operating parameters, preferred behaviors, and the like. The customization module may define the operation of one or more modules of the source device 2402. The customization module may, for example, used to store settings defining the thresholds or configurations for the indicators.

In some embodiments the source device may include one or more processing elements 2448. The processing element may include a processor, a programmable gate array, an application specific integrated circuit, and/or the like that may be used to coordinate the operation of the system, run control algorithms, process optimization protocols, and control one or more of the modules of the source device.

In embodiments the power electronics module 2414, communication module 2412, sensors, and other elements of the source device 2402 may receive power from the power module 2406. The power module 2406 may provide DC or AC power to the elements and module from one or more batteries, from AC mains source, and/or the like.

The magnetic fields generated by the one or more resonators 2404 of the source device 2402 may be captured by one or more repeater resonators 2418 of the repeater device 2434. The repeater device may be physically independent from the source device 2402. The repeater device 2434 may be freely movable independently of the source device 2402. In some embodiments the source device and the repeater device may include one or more indentations, protrusions, shaped areas, and/or other physical and/or visual positioning aids. The positioning aids may be used as convenient way to align or position the source device and one or more repeater devices in a specific orientation and relative position.

The repeater device 2434 may include one or more repeater resonators 2418 as described herein. The repeater resonators 2418 may capture the oscillating magnetic fields generated by the source device 2402 and extend, focus, redistribute, and/or the like the magnetic fields as described herein in other parts of this application. In embodiments and configurations shown in FIG. 22 for example, the one or more repeater resonators 2418 may be used to redistribute the magnetic fields generated by the source device resonators 2404 over a larger area such that the magnetic energy may be captured by one or more receiving devices 2440 such as phones, tablets, computers, and the like that are designed with or have magnetic resonators configured to capture the magnetic energy.

In some embodiments the repeater resonators may passive. The repeater resonators may be statically tuned to a specific frequency which may be 5% or 10% or less below or above the frequency of the magnetic fields generated by one or more resonators of the source device. In embodiments the repeater device 2434 may have more than one repeater resonator 2418 and one or more of the resonators may be statically tuned to different resonant frequencies. In embodiments with more than one repeater resonators 2418 the repeater resonators may all be the same type of resonators. In other embodiments the repeater resonators 2418 may include one or more resonators or all resonators having a different shape, size, type, orientation, frequency, properties, and the like.

In some embodiments, the one or more repeater resonators 2418 of the repeater device 2434 may be tunable and/or actively tuned. One or more of the repeater resonators 2418 may have a tunable or adjustable frequency, inductance, resistance, impedance, shape, magnetic field characteristics, and/or the like. The tunability of the resonators may be achieved or enabled by tunable elements such as adjustable capacitors, banks of capacitors, inductors, networks of capacitors and/or inductors and/or other tunable components. A repeater device 2434 may include one or more passive repeater resonators and one or more tunable repeater resonators.

In embodiments the repeater device 2434 may further include one or more sensors 2424. The sensors may include magnetic field sensors, electric field sensors, voltage sensors, current sensors, frequency sensors, and/or the like. The sensors may be used to determine the operating characteristics of a field generated by a source device, for example. Magnetic field sensors may be used to determine the frequency, magnitude, phase, orientation, and the like of fields around or near the repeater device. Based on the readings of the sensors, the elements of the repeater device may be adjusted to improve coupling and the power transfer efficiency by, for example, tuning the resonant frequency of one or more repeater resonators 2418 to match the resonant frequency of the detected fields. Based on the readings of the sensors, any of the adjustable parameters of the repeater device 2434 may be adjusted and/or may be communicated to other devices in the system using the communications module 2426.

In embodiments the repeater device may include indicators 2422 which may be used to generate one or more auditory, visual, tactile, wireless signal, and/or the like feedback to a user or operator regarding the status of the system, devices, components, field strength, and/or the like. Indicators may be lights, LEDs, graphic displays, audio speakers, vibrators, lasers, optical output devices, and the like. Indicators may show that the repeater device is energized, the status of a repeater device, and the like. The indicators may display the charging status of one or more receiving devices and the expected time to finish charging, for example. Similarly to the indicators of the source device, the indicators may be configurable and/or customizable.

In embodiments the repeater device 2434 may also include a configuration storage module 2430. The configuration storage module 2430 may include one or more preconfigured operating configurations for the repeater device. The operating configurations may define the tuning characteristics for one or more of the resonators of the repeater device. The repeater device may be configured to operate in more than one environment with different source devices, for example. In each environment the tuning parameters of the resonators in each environment and/or for each source device may be different. The resonant frequency of the repeater device may need to be adjusted due to perturbations from objects in the environment, for example. The tuning or operating parameters for the resonators may be determined by the system with an initial tuning or configuration procedure that calculates or empirically determines suitable operating and tuning parameters for the configuration. Once the parameters are determined they may be stored in the configuration module 2430 to avoid running the tuning or configuration procedure when the same environment or source device is encountered. In some embodiments the repeater device 2434 may also include a communication module 2426.

The communication module may include necessary antennas, protocols, logic, and controllers for use of one or more out-of-band communication channels and technologies such as Wifi, Bluetooth, Zigbee, and the like. In some embodiments, the communication module may include, or include instead the necessary components, controllers, protocols, and the like for in-band communication with other repeater devices, source devices, and receiver devices. The in-band communication may utilize the resonators and/or the wireless energy transfer fields to send information.

In embodiment the repeater device may include a power module 2420. The power module may control, capture and/or siphon a small percentage of the usable power available at the one or more repeater resonators of the repeater device and provide DC or AC power to one or more of the modules of the repeater device. The communication module and/or the sensors module may receive power from the power module. In some embodiments the power module may include one or more batteries and/or other energy storage elements. The power module may be configured to control and change the mode of operation of the repeater device. In some embodiments, the one or more repeater resonators of the repeater device may be configurable to operate in a normal repeater mode, as well as in an energy capture mode, and even in an energy source mode.

In some embodiments, the repeater device may be configured to operate as a repeater device but with a portion of the energy received by the repeater device used to charge or maintain a charge on one or more batteries and/or energy storage elements of the repeater device. One or more of the repeater resonators of the repeater device may be temporarily configured and operated as a source, generating oscillating magnetic fields from the energy stored in the battery and/or energy storage elements. In some embodiments, a source mode of the repeater device may be used or activated when the energy delivery from a source is interrupted. The source mode may be activated when the fields, voltages, currents, and/or the like measured by the sensors at or near the repeater device fall below a specific threshold. In a situation when a source gets knocked off the table, for example, and is no longer able to deliver power, the repeater device may sense a dropping voltage and/or current on one or more of the repeater resonators. The power module 2420 may active the source mode of the repeater device to temporarily power a receiving device until energy delivery from the source device is restored. The repeater device may in some embodiments activate one or more of its indicators 2422 to alert the user that the repeater device is operating in a source mode. In some embodiments the repeater device may transmit an alert to the source device to active one or more indicators 2408 on the source device to alert the user that the repeater device is not receiving enough energy. In some embodiments, the power module 2420 of the repeater device 2434 may activate the source mode for one or more of the repeater resonators using energy from an internal battery to provide a temporary or momentary boost of energy to one or more receiver devices.

It is to be understood that FIG. 24 includes many optional elements and modules in the system. Some modules may be omitted from the system depending on the cost, size, power, and other constraints. Omitting an element may reduce some features of the system and may reduce the functionality of the system by removing the capabilities described with the particular element or module. For example, indicators 2422 of the repeater device 2434 may be optional in some embodiments. In repeater devices embedded in counter tops, for example, there may not be a practical or inexpensive way of providing indicators to a user.

In embodiments the system may have one or more wireless energy transfer channels and communication channels between the components and devices of the system. The wireless energy transfer channels and the communication channels may be virtual channels or channels characterized and defined by specific communication protocols, frequencies, and the like. In embodiments a source device may have an energy transfer channel 2436 between the source device and the repeater device. Another energy transfer channel 2448 may also be established between the receiving device and the repeater device. Yet another energy transfer channel may also exist between the receiving device and the source device 2402. These wireless energy transfer channels may be codependent and may be based on energy transfer using oscillating magnetic fields that are at, or substantially near, the same frequencies, phase, and the like. In embodiments a receiving device, for example, may receive energy from the repeater device and the source device at substantially the same frequency simultaneously with parameters controlled by the source device. Changes in power delivery to the receiving device may only be made with changes of output power, or other changes in characteristics at the source device.

In some embodiments the wireless energy transfer channel between the devices of the system may be controlled, at least in part, independently from one another. Energy transfer from the source device to the receiving device may be at least in part controlled by a repeater device independently from the energy and magnetic fields generated by the source device. For example, the source device may continuously generate and output the same energy level with the same intensity, magnitude, and/or frequency of magnetic fields while the repeater device may control the energy transfer from the repeater device to the receiving device by detuning one or more repeater resonators away from the parameters of the source device.

The source device may be smaller than the repeater device. In other embodiments the source device may be a similar size or larger than the repeater device. In embodiments a system may include more than one source device 2402 and one or more repeater devices 2434. The repeater devices may be positioned below, above, next to, or behind the source device. In some embodiments repeater devices may located under a work surface, behind a wall, in a drawer under a work surface and the like. In some embodiments the repeater device may be embedded in the work surface in plastic, coriander, glass, and the like. In some applications the repeater device may not be visible and not marked and it may be difficult to visually determine the area of the work surface that has the repeater device. It may be difficult to visually determine where to locate or place the source device or the receiver devices to couple to the repeater device. In embodiments the source device may be used to determine and map the location of a repeater device that may be embedded in a work surface or not visible.

In embodiments the source device may be configurable as a repeater device locator. In some embodiments a source device may be movable and may measure the magnetic fields, voltages, currents, and/or impedance at or near one or more of the source resonators. In embodiments the source device may energize one or more of its source resonators. The source device may measure the currents and/or voltages on the source resonator. Based on the behavior of the voltages and/currents at one or more of the source resonators as the source is being moved, a change in impedance, load, resistance, power draw, and the like at the source resonator may be detected. The change in the load, for example may signify strong coupling to a repeater resonator. Indicators on the source device, such as lights, LEDs, or a display may be used to indicate the presence or absence of a repeater device at the location or near the location of the source. As the source is moved, a change of an indication may be used to determine the boundaries of a repeater resonator.

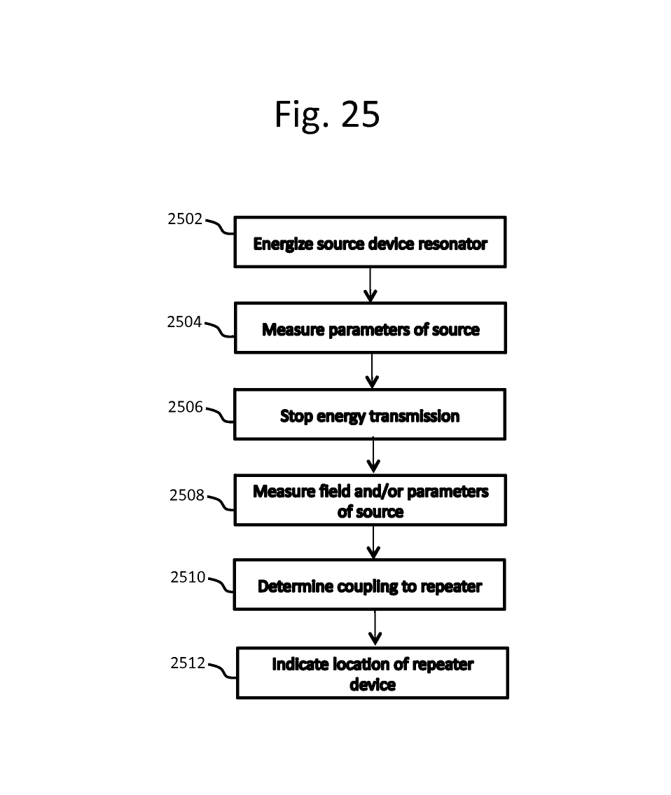

Another example method for determining the location and boundaries of a repeater device using a source device is outlined in FIG. 25. The method may start with positioning the source device in one location and energizing the one or more resonators of the source device. The source device resonators may be energized to generate a magnetic field at block 2502. In block 2504 the sensors of the source device may measure the field parameters and/or voltage on the energized resonator(s). Based on the measurements, the impedance or the load on the source resonator may be determined. Increased impedance at the source resonator from an expected value may signify the presence of a repeater device in close proximity. In block 2506 the source resonator may optionally continue the detection procedure. If the procedure is continued the source device may stop energizing the source resonator. In block 2508 sensors of the source device may be used to measure magnetic fields and/or voltages and currents on the source resonator. The time required for the oscillating magnetic fields and/or the voltages at or near the source repeater to die down below a set threshold may depend on the proximity of the source device and repeater resonators. Based on the sensor readings, in block 2510, the source may determine the coupling between the source device and the repeater device and hence the relative position and/or distance between the repeater and the source. In block 2512 the source device may provide an indication if the repeater device is in near proximity (i.e. 10 cm or less, or 2 cm or less) to the source device.

The repeater device may comprise one or more coils or repeater resonators arranged in a line, or a multi-dimensional array to extend the “x-y” dimensions of this system energized volume. In embodiments the system may include more than one repeater device arranged in a line or a multi-dimensional array. The system may be used to deliver power to items on desks, bars, tables, stands, shelves and the like. The system may be used to deliver power to promotional items in a restaurant, coffee shop, or bar. The system may be used in a store to deliver energy to devices that may highlight products, product packaging, and the like.

While the invention has been described in connection with certain preferred embodiments, other embodiments will be understood by one of ordinary skill in the art and are intended to fall within the scope of this disclosure, which is to be interpreted in the broadest sense allowable by law.

Unless otherwise indicated, this disclosure uses the terms wireless energy transfer, wireless power transfer, wireless power transmission, and the like, interchangeably. Those skilled in the art will understand that a variety of system architectures may be supported by the wide range of wireless system designs and functionalities described in this application.

This disclosure references certain individual circuit components and elements such as capacitors, inductors, resistors, diodes, transformers, switches and the like; combinations of these elements as networks, topologies, circuits, and the like; and objects that have inherent characteristics such as “self-resonant” objects with capacitance or inductance distributed (or partially distributed, as opposed to solely lumped) throughout the entire object. It would be understood by one of ordinary skill in the art that adjusting and controlling variable components within a circuit or network may adjust the performance of that circuit or network and that those adjustments may be described generally as tuning, adjusting, matching, correcting, and the like. Other methods to tune or adjust the operating point of the wireless power transfer system may be used alone, or in addition to adjusting tunable components such as inductors and capacitors, or banks of inductors and capacitors. Those skilled in the art will recognize that a particular topology discussed in this disclosure can be implemented in a variety of other ways.

Unless otherwise defined, all technical and scientific terms used herein have the same meaning as commonly understood by one of ordinary skill in the art to which this disclosure belongs. In case of conflict with publications, patent applications, patents, and other references mentioned or incorporated herein by reference, the present specification, including definitions, will control.

Any of the features described above may be used, alone or in combination, without departing from the scope of this disclosure. Other features, objects, and advantages of the systems and methods disclosed herein will be apparent from the following detailed description and figures.

All documents referenced herein are hereby incorporated by reference in their entirety as if fully set forth herein.

What is claimed is:

1. A system for wireless energy distribution over a volume, the system comprising:
a source device coupled to an energy source, the source device comprising at least one source resonator that is configured to generate an oscillating magnetic field with a frequency and wherein the source device has a source energized volume; and
at least one repeater device, the repeater device comprising at least one repeater resonator and positioned in a defined area and in coupling proximity to the source device;
wherein the repeater device provides an effective wireless energy system energized volume that is larger than the source energized volume,
wherein the source device is operable to detect the presence of a repeater device.

2. The system of claim 1, wherein the repeater device is positioned under a work surface and the source device is positioned on top of the work surface.

3. The system of claim 1, wherein the repeater device is embedded in a work surface and the source device is positioned on top of the work surface.

4. The system of claim 1, wherein the repeater device is embedded in a work surface and the source device is positioned below the work surface.

5. The system of claim 1, wherein the repeater device is above a work surface and the source device is positioned below the work surface.

6. The system of claim 1, wherein at least one repeater resonator of the repeater device has a characteristic size larger than the characteristic sizes of the source resonators of the source device.

7. The system of claim 1, wherein the source device further comprises indicators, the indicators configured to indicate the coupling strength between the source device and the repeater device.

8. The system of claim 1, wherein the repeater device further comprises a battery.

9. The system of claim 8, wherein at least one repeater resonator of the repeater device is configurable to operate as an energy source energized at least in part by electrical energy stored in the battery.

10. A method of detecting the location of a repeater device using a source device, the method comprising:
energizing a source resonator of the source device;
measuring a voltage and a current on the source resonator;
comparing the voltage and current measurements with expected measurements;
determining if a repeater resonator of the repeater device is within a coupling distance to the source resonator; and
indicating presence of a repeater resonator within the coupling distance.

11. The method of claim 10, further comprising the steps of:
stopping the energizing of the source resonator;
measuring the voltage on the source resonator;
determining a time for the voltage to decay below a threshold; and
determining if the repeater resonator is within the coupling distance to the source resonator based at least in part on the time.

12. The method of claim 10, further comprising the steps of:
stopping the energizing of the source resonator;
measuring a magnetic field on the source resonator;
determining a time for the magnetic field to decay below a threshold; and
determining if the repeater resonator is within the coupling distance to the source resonator based at least in part on the time.

13. The method of claim 10, further comprising the steps of:
stopping the energizing of the source resonator;
measuring the current on the source resonator;
determining a time for current to decay below a threshold; and
determining if the repeater resonator is within the coupling distance to the source resonator based at least in part on the time.

14. The method of claim 10, wherein the coupling distance is less than 5 cm.

15. The method of claim 10, wherein the coupling distance is less than 10 cm.

16. The system of claim 1, wherein the source device is operable to detect the repeater resonator by measuring the impedance of one or more source resonators.

17. The system of claim 1, wherein the source device is operable to detect the repeater resonator by measuring a decay time of the magnetic field.

18. The system of claim 1, wherein the source device is operable to detect the repeater resonator by measuring a decay time of the voltage.

19. The system of claim 1, wherein the source device is operable to detect the repeater resonator by measuring a decay time of the current.
